(19) United States
(12) Patent Application Publication
(10) Pub. No.: US 2026/0244049 A1
(43) Pub. Date: Aug. 20, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Byeong Hee WON, Yongin-si (KR); Beom Shik KIM, Yongin-si (KR); Eun Kyoung NAM, Yongin-si (KR)

(21) Appl. No.: 19/423,183

(22) Filed: Dec. 17, 2025

(30) Foreign Application Priority Data
Feb. 20, 2025 (KR) 10-2025-0022059

(51) Int. Cl. G02F 1/1335; G02F 1/13; G09G 3/36

(52) U.S. Cl. CPC G02F 1/133526; G02F 1/1323; G09G 3/3688; G09G 2320/0247

(57) ABSTRACT

A display device includes a display driver that outputs an image data voltage, a display panel including a first refractive area and a second refractive area in which a plurality of light emitting elements that receive the image data voltage from the display driver and emit light is disposed, and an optical lens unit configured to refract the light emitted from the plurality of light emitting elements disposed in the first refractive area and the light emitted from the plurality of light emitting elements disposed in the second refractive area. The image data voltage includes a plurality of data voltages supplied to the light emitting elements, respectively, and a plurality of compensation data voltages derived based on the data voltages, the light emitting elements disposed in the first refractive area receive the data voltages, and the light emitting elements disposed in the second refractive area receive the compensation data voltages.

### CROSS-REFERENCE TO RELATED APPLICATIONS

This application claims priority under 35 U.S.C. § 119 to Korean Patent Application No. 10-2025-0022059, filed on February 20, 2025, the disclosure of which is incorporated by reference herein in its entirety.

### TECHNICAL FIELD

Embodiments of the present disclosure relate to a display device and an electronic device including the same.

### DISCUSSION OF RELATED ART

With the development of communications technology and media, display devices are being used to display images in various places and environments. For example, various types of display devices, such as liquid crystal displays (LCDs) and organic light emitting diode (OLED) displays, are being widely used.

Recently, a stereoscopic image display device, which divides an image of the display device and displays the divided image in a space in front of the display device by using a lens array, has been developed. The stereoscopic image display device includes a binocular parallax type which displays a left-eye image and a right-eye image separately to provide a three-dimensional (3D) effect due to binocular parallax and a light field type which converges light emitted from each lens of the lens array onto a view area where a viewer observes the display device.

### SUMMARY

Embodiments of the present disclosure provide a display device with improved display quality.

According to various embodiments of the present disclosure, a display device includes a display driver that outputs an image data voltage, a display panel including a first refractive area and a second refractive area in which a plurality of light emitting elements that receive the image data voltage from the display driver and emit light is disposed and an optical lens unit configured to refract the light emitted from the plurality of light emitting elements disposed in the first refractive area and the light emitted from the plurality of light emitting elements disposed in the second refractive area. The image data voltage includes a plurality of data voltages respectively supplied to the light emitting elements and a plurality of compensation data voltages derived based on the data voltages. The light emitting elements disposed in the first refractive area receive the data voltages, and the light emitting elements disposed in the second refractive area receive the compensation data voltages.

According to various embodiments of the present disclosure, the light emitted from the light emitting elements disposed in the first refractive area forms a first viewing angle and a second viewing angle, and the light emitted from the light emitting elements disposed in the second refractive area forms a third viewing angle and a fourth viewing angle.

According to various embodiments of the present disclosure, the light emitted from the light emitting elements disposed in the first refractive area forms a first viewing angle and a second viewing angle, and in the first refractive area, a data voltage input to a light emitting element that emits light forming the first viewing angle may be different from a data voltage input to a light emitting element that emits light forming the second viewing angle.

According to various embodiments of the present disclosure, a plurality of data voltages input to a plurality of light emitting elements that emit light forming the first viewing angle in the first refractive area are formed from first data collected for specific content at the first viewing angle, and a plurality of data voltages input to a plurality of light emitting elements that emit light forming the second viewing angle in the first refractive area may be formed from second data collected for the specific content at the second viewing angle.

According to various embodiments of the present disclosure, the light emitted from the light emitting elements disposed in the second refractive area forms a first viewing angle and a second viewing angle, and in the second refractive area, a compensation data voltage input to a light emitting element that emits light forming the first viewing angle may be as about equal to a compensation data voltage input to a light emitting element that emits light forming the second viewing angle.

According to various embodiments of the present disclosure, a plurality of compensation data voltages input to a plurality of light emitting elements that emit light forming the first viewing angle in the second refractive area are formed from third data derived from the first data collected for specific content at the first viewing angle, and a plurality of compensation data voltages input to a plurality of light emitting elements that emit light forming the second viewing angle in the second refractive area may be formed from the third data.

According to various embodiments of the present disclosure, light emitted from the first refractive area forms the first viewing angle and the second viewing angle, and in the first refractive area, a data voltage input to a light emitting element that emits light forming the first viewing angle may be different from a data voltage input to a light emitting element that emits light forming the second viewing angle.

According to various embodiments of the present disclosure, a plurality of data voltages input to a plurality of light emitting elements that emit light forming the first viewing angle in the first refractive area may be different from a plurality of compensation data voltages input to a plurality of light emitting elements that emit light forming the first viewing angle in the second refractive area.

According to various embodiments of the present disclosure, a plurality of data voltages input to a plurality of light emitting elements that emit light forming the first viewing angle in the first refractive area are formed from the first data, and a plurality of compensation data voltages input to a plurality of light emitting elements that emit light forming the first viewing angle in the second refractive area may be formed from the third data.

According to various embodiments of the present disclosure, the plurality of data voltages are formed from first data generated by collecting specific content at a first viewing angle and second data generated by collecting the specific content at a second viewing angle, and the plurality of compensation data voltages may be formed from third data derived based on the first data.

According to various embodiments of the present disclosure, the plurality of light emitting elements disposed in the first refractive area may receive a data voltage input to the first refractive area among the first data and a data voltage input to the first refractive area among the second data.

According to various embodiments of the present disclosure, the plurality of light emitting elements disposed in the second refractive area may receive a compensation data voltage input to the second refractive area among the third data.

According to various embodiments of the present disclosure, the plurality of light emitting elements disposed in the first refractive area may receive a data voltage input to the first refractive area among the first data and a data voltage input to the first refractive area among the second data.

According to various embodiments of the present disclosure, the third data may include data obtained by processing the first data using a blur technique.

According to various embodiments of the present disclosure, the blur technique may be any one selected from the group consisting of Gaussian blur, box blur, median blur, motion blur, and bilateral blur teqhnique.

According to various embodiments of the present disclosure, an electronic device includes a processor that provides an image signal, a display device that receives the image signal from the processor and displays an image, and a power device that supplies power to the display device. The display device includes a display panel including a first refractive area and a second refractive area in which a plurality of light emitting elements that receive the image signal and emit light are disposed, and an optical lens unit configured to refract light emitted from a plurality of light emitting elements disposed in the first refractive area and light emitted from a plurality of light emitting elements disposed in the second refractive area. The image signal includes a plurality of data voltages respectively supplied to the light emitting elements and a plurality of compensation data voltages derived based on the data voltages. The light emitting elements disposed in the first refractive area receive the data voltages, and the light emitting elements disposed in the second refractive area receive the compensation data voltages.

According to various embodiments of the present disclosure, light emitted from the first refractive area forms a first viewing angle and a second viewing angle, and in the first refractive area, a data voltage input to a light emitting element that emits light forming the first viewing angle may be different from a data voltage input to a light emitting element that emits light forming the second viewing angle.

According to various embodiments of the present disclosure, light emitted from the second refractive area forms a first viewing angle and a second viewing angle, and in the second refractive area, a compensation data voltage input to a light emitting element that emits light forming the first viewing angle may be the same as a compensation data voltage input to a light emitting element that emits light forming the second viewing angle.

According to various embodiments of the present disclosure, the plurality of data voltages include first data generated by collecting specific content at a first viewing angle and second data generated by collecting the specific content at a second viewing angle, and the plurality of compensation data voltages may include third data derived based on the first data.

According to various embodiments of the present disclosure, the plurality of light emitting elements disposed in the first refractive area receive a data voltage input to the first refractive area among the first data and a data voltage input to the first refractive area among the second data, and the plurality of light emitting elements disposed in the second refractive area may receive a compensation data voltage input to the second refractive area among the third data.

A display device according to an embodiment of the present disclosure can reduce display resolution reduction that may occur in an area where a two-dimensional (2D) image is realized in a case in which both a 2D image and a three-dimensional (3D) image are realized in one display device. Therefore, the display quality of the display device can be improved.

### BRIEF DESCRIPTION OF THE DRAWINGS

The above and other features of the present disclosure will become more apparent by describing in detail embodiments thereof with reference to the accompanying drawings, in which:

FIG. 1 is an exploded perspective view of a display device according to an embodiment of the present disclosure;

FIG. 2 is a perspective view of the display device according to FIG. 1;

FIG. 3 is a cross-sectional view of a portion of a display device including emission areas;

FIG. 4 is a cross-sectional view of a first type of light field display in which a two-dimensional (2D) image is realized;

FIG. 5 is a cross-sectional view of a first type of light field display in which a three-dimensional (3D) image is realized;

FIG. 6 is a cross-sectional view of a second type of light field display in which a 2D image is realized;

FIG. 7 is a cross-sectional view of a second type of light field display in which a 3D image is realized;

FIG. 8 is a cross-sectional view illustrating a case in which a 2D image is realized in an area where light is not refracted;

FIG. 9 is a cross-sectional view illustrating a case in which a 3D image is realized in an area where light is refracted;

FIG. 10 is a cross-sectional view illustrating a case in which a 2D image is realized in an area where light is refracted;

FIG. 11 is a cross-sectional view illustrating light incident on a user’s right eye in the area where light is refracted to realize a 2D image;

FIG. 12 is a cross-sectional view illustrating light incident on the user’s left eye in the area where light is refracted to realize a 2D image;

FIG. 13 is a cross-sectional view illustrating light incident on a user’s right eye in a display device according to an embodiment of the present disclosure;

FIG. 14 is a cross-sectional view illustrating light incident on the user’s left eye in the display device according to an embodiment of the present disclosure;

FIG. 15 is a cross-sectional view illustrating light incident on both eyes of the user in the display device according to an embodiment of the present disclosure;

FIG. 16 is a plan view illustrating the arrangement of subpixels in a display device according to an embodiment of the present disclosure;

FIG. 17 is a plan view illustrating viewing angles or view areas mapped to the subpixels arranged in the display device according to an embodiment of the present disclosure;

FIG. 18 is a plan view illustrating a first refractive area according to an embodiment of the present disclosure;

FIG. 19 is a plan view illustrating a second refractive area according to an embodiment of the present disclosure;

FIG. 20 is a plan view illustrating subpixels which emit light to be incident on a user’s right eye in refractive areas according to an embodiment of the present disclosure;

FIG. 21 is a plan view schematically illustrating data voltages and compensation data voltages applied to the subpixels which emit light to be incident on the user’s right eye in the refractive areas according to an embodiment of the present disclosure;

FIG. 22 is a plan view illustrating subpixels which emit light to be incident on a user’s left eye in refractive areas according to an embodiment of the present disclosure;

FIG. 23 is a plan view schematically illustrating data voltages and compensation data voltages applied to the subpixels which emit light to be incident on the user’s left eye in the refractive areas according to an embodiment of the present disclosure;

FIGS. 24 through 30 are plan views schematically illustrating positional criteria for determining compensation data voltages according to an embodiment of the present disclosure;

FIG. 31 is a block diagram of an electronic device according to an embodiment of the present disclosure; and

FIG. 32 is a schematic diagram of electronic devices according to various embodiments of the present disclosure.

### DETAILED DESCRIPTION

Embodiments of the present disclosure will be described more fully hereinafter with reference to the accompanying drawings. Like reference numerals may refer to like elements throughout the accompanying drawings.

It will be further understood that terms such as “comprise,” “include,” and “have,” when used herein, specify a presence of stated features, integers, steps, operations, elements, and/or components, but do not preclude the presence or addition of one or more other features, integers, steps, operations, elements, components, and/or groups thereof.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

Spatially relative terms, such as “beneath”, “below”, “lower”, “under”, “above”, “upper”, etc., may be used herein for ease of description to describe one element or feature’s relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art, for example, within ± 30%, 20%, 10% or 5% of the stated value. Further, it is to be understood that while parameters may be described herein as having “about” a certain value, according to embodiments, the parameter may be exactly the certain value or approximately the certain value within a measurement error as would be understood by a person having ordinary skill in the art. Other uses of these terms and similar terms to describe the relationships between components should be interpreted in a like fashion.

Embodiments of the present disclosure relate to a display device that includes both a first refractive area configured for stereoscopic image display and a second refractive area configured for two-dimensional (2D) image display. In such hybrid displays, resolution degradation in the 2D region can occur due to angular spreading of light through an optical lens unit. For example, when a 2D image is viewed in the second refractive area, the same image data may be emitted across multiple subpixels associated with different viewing angles, resulting in a reduced effective resolution as perceived by the user’s eyes.

To address this issue, the display device according to embodiments of the present disclosure supplies data voltages and compensation data voltages to subpixels based on image data collected or derived at multiple view angles. In the first refractive area, separate image data may be supplied to left-eye and right-eye view areas to produce a stereoscopic effect. In the second refractive area, compensation data voltages are derived by processing original image data, such as by applying a blur technique or weighted combination across view angles. This may enable the light refracted toward each eye to exhibit angular variation, improving the perceptual continuity and spatial definition of the 2D image.

As a result, the display device according to embodiments of the present disclosure may improve the effective resolution of 2D images in the refractive region without modifying the physical pixel structure or optical lens configuration. By generating compensation data voltages that emulate inter-view variation, embodiments may reduce artifacts such as, for example, blur, ghosting, or loss of edge clarity that typically accompany 2D image rendering in refracted regions of a light field–type panel. This allows for a more consistent and visually accurate 2D display experience, including in devices that must support both 2D and 3D display modes.

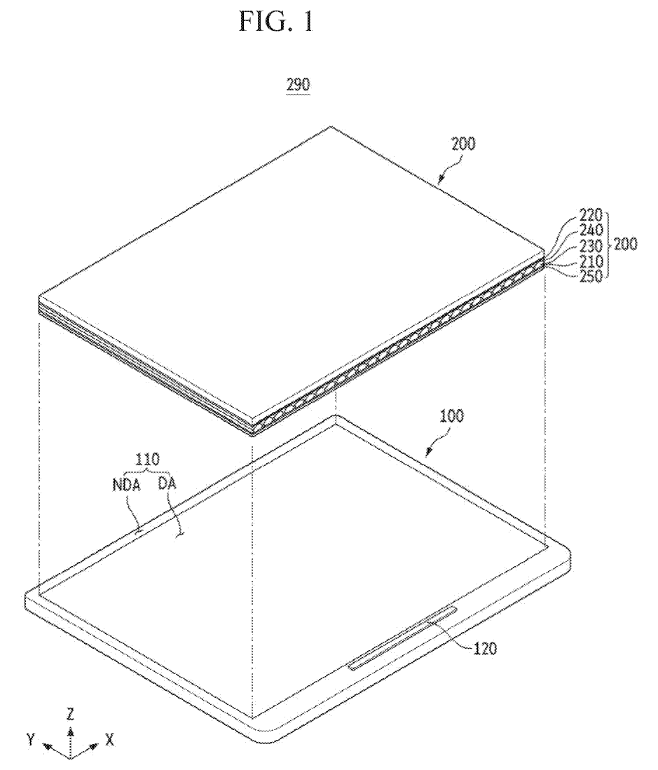

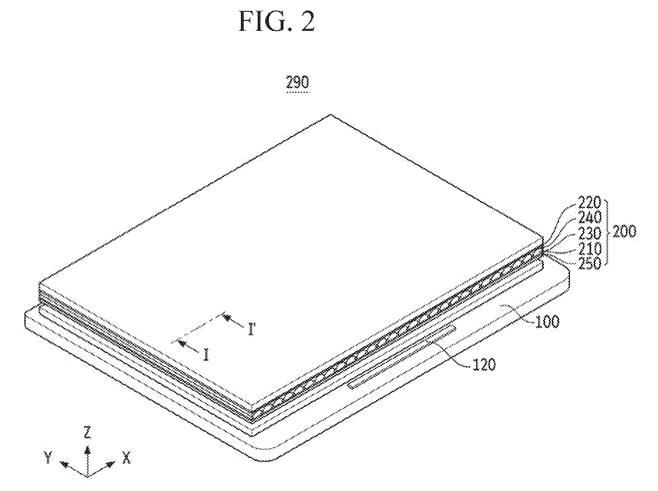

FIG. 1 is an exploded perspective view of a display device 290 according to an embodiment of the present disclosure. FIG. 2 is a perspective view of the display device 290 according to FIG. 1.

The display device 290 may be implemented as, for example, a flat panel display device such as a liquid crystal display (LCD), a field emission display (FED), a plasma display panel (PDP), or an organic light emitting display (OLED).

The display device 290 may be a stereoscopic image display device, for example, a three-dimensional (3D) image display device, which includes a display module 100 and an optical member 200. To display a 3D image, the stereoscopic image display device may display a left-eye image and a right-eye image separately in front of the display device to provide a 3D effect due to binocular parallax. Furthermore, the stereoscopic image display device may provide a plurality of viewing angle images separately in front of the display device to show different images at different viewing angles.

The display device 290 according to an embodiment may be a light field display in which the optical member 200 is disposed in front of the display module 100, so that different image information is shown to both eyes of a viewer. The light field display may generate a light field and create a 3D stereoscopic image by using the display module 100 which displays a two-dimensional (2D) image and the optical member 200 which converts the 2D image into a 3D image and displays the 3D image. As will be described further below, in the light field display, image display light generated by each pixel of the display module 100 is made to form a light field in a specific direction (at a specific viewing angle and/or a specific point in time) by a stereoscopic lens, a pinhole, or a barrier included in the optical member 200. Accordingly, 3D stereoscopic image information corresponding to the specific direction may be provided to a viewer.

The display module 100 may include a display panel 110 and a display driver 120.

The display panel 110 may include a display area DA and a non-display area NDA. The display area DA may include data lines, scan lines, voltage supply lines, and a plurality of pixels connected to corresponding data lines and scan lines. For example, the scan lines may extend in a first direction (e.g., an X-axis direction) and may be spaced apart from each other in a second direction (e.g., a Y-axis direction). The data lines and the voltage supply lines may extend in the second direction (e.g., the Y-axis direction) and may be spaced apart from each other in the first direction (e.g., the X-axis direction).

Each pixel (or unit pixel) formed and arranged in the display panel 110 includes a minimum number of subpixels that can display white. For example, each pixel may include three subpixels that display red light, green light, and blue light, respectively. Each of the subpixels, which are arranged alternately, may be connected to at least one scan line, a data line, and a power supply line. Each of the subpixels may include thin-film transistors, which include a driving transistor and at least one switching transistor, a light emitting element, and a capacitor. Each of the pixels may receive a data voltage of a data line when a scan signal is transmitted from a scan line and may emit light by supplying a driving current to a light emitting element according to the data voltage applied to a gate electrode.

In the present specification, the pixels (e.g., the unit pixels) of the display panel 110 display a 2D multi-view image according to the image data supply order of the display driver 120. The multi-view image includes n view images (where n is a positive integer equal to or greater than 2). Here, the n view images are images generated by capturing images of a specific object (or content) using n cameras spaced apart from each other by a distance between both eyes of an ordinary person.

For example, the n view images may include first data generated by collecting specific content at a first viewing angle, second data generated by collecting the specific content at a second viewing angle, …, n^{th} data generated by collecting the specific content at an n^{th} viewing angle. A plurality of data (the first data through the n^{th} data) generated by photographing the specific content may be digital data.

The display panel 110 may display a multi-view image in units of n pixels during an image display period. For example, the display panel 110 may display a multi-view image in units of two pixels. That is, two pixels of the display panel 110 may display a multi-view image including two view images. For example, the display panel 110 may display a multi-view image in units of a time-division frame (or subframe) period according to the time-division driving of the display driver 120. In this case, a multi-view image may be displayed in units of two pixels for each time-division frame period. The time-division frame period is a period in which one frame period is divided into 1/2 or 1/3 frame periods.

The non-display area NDA may surround the display area DA at edges of the display panel 110. The non-display area NDA may include a scan driver which transmits scan signals to scan lines and pads which are connected to the display driver 120. For example, the display driver 120 may be disposed on a side of the non-display area NDA, and the pads may be disposed on an edge of the non-display area NDA where the display driver 120 is disposed.

The display driver 120 may output control signals and image data voltages for driving the display panel 110 in units of at least one frame or in units of at least one time-division frame (or subframe). For example, the display driver 120 may supply image data voltages to data lines in units of at least one time-division frame (or subframe). The display driver 120 may supply a power supply voltage to a power supply line and may supply scan control signals to the scan driver. The image data voltages may include a plurality of data voltages which are supplied to a plurality of pixels (or subpixels) connected to a plurality of data lines.

The optical member 200 includes an optical lens unit 230 (e.g., refractive anisotropic lenses) which is formed between first and second base substrates 210 and 220, a polarization control unit 250 which is stacked and overlapped with the optical lens unit 230, and a filler layer 240 which fills a space between the optical lens unit 230 and the second base substrate 220.

In an embodiment, the display driver 120 may be formed as an integrated circuit (IC) and disposed in the non-display area NDA of the display panel 110 using a chip on glass (COG) method, a chip on plastic (COP) method, or an ultrasonic bonding method. In an embodiment, the display driver 120 may be mounted on a circuit board and connected to the pads of the display panel 110.

The optical member 200 may be disposed in front of the display panel 110 or the display module 100. The optical member 200 may be attached to a surface of the display panel 110 or the display area DA through an adhesive member. The optical member 200 may be bonded to the front of the display module 100 by a panel bonding device.

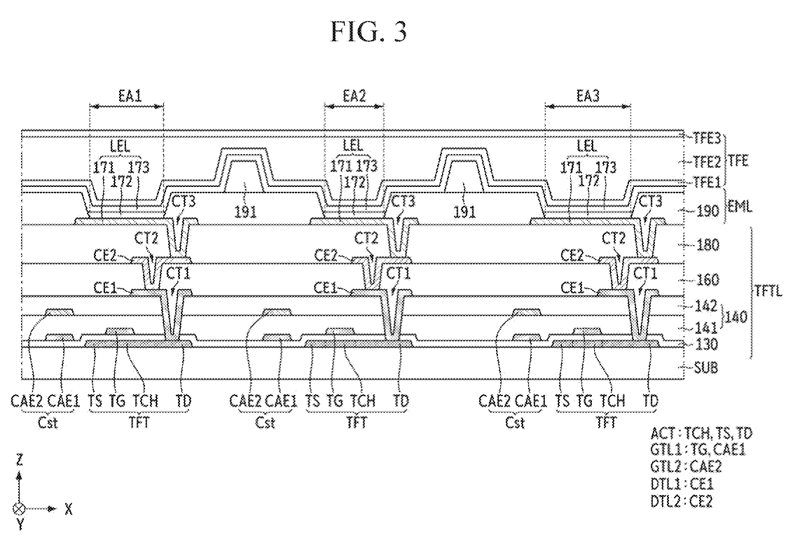

FIG. 3 is a cross-sectional view of a portion of a display device including emission areas.

Referring to FIG. 3, a display panel 110 may include a substrate SUB, a thin-film transistor layer TFTL, a light emitting element layer EML, and an encapsulation layer TFE.

The thin-film transistor layer TFTL may include an active layer ACT, a first gate metal layer GTL1, a second gate metal layer GTL2, a first data metal layer DTL1, and a second data metal layer DTL2. In addition, the thin-film transistor layer TFTL may include a buffer layer BF, a gate insulating layer 130, a first interlayer insulating film 141, a second interlayer insulating film 142, a first planarization layer 160, and a second planarization layer 180. The thin-film transistor layer TFTL may include a plurality of thin-film transistors TFT, and each of the thin-film transistors TFT may include a channel TCH, a gate electrode TG, a first electrode TS, and a second electrode TD.

The active layer ACT may be disposed on the substrate SUB. The active layer ACT may include a silicon semiconductor, such as polycrystalline silicon, monocrystalline silicon or low-temperature polycrystalline silicon, or may include an oxide semiconductor.

The active layer ACT may include the channel TCH, the first electrode TS and the second electrode TD of each of the thin-film transistors TFT. The channel TCH may be a region overlapped by the gate electrode TG of a thin-film transistor TFT in a third direction (e.g., a Z-axis direction), which is a thickness direction of the substrate SUB. The first electrode TS may be disposed on a side of the channel TCH, and the second electrode TD may be disposed on the other side of the channel TCH. The first electrode TS and the second electrode TD may be regions not overlapped by the gate electrode TG in the third direction (e.g., the Z-axis direction). The first electrode TS and the second electrode TD may be regions formed to have conductivity by doping a silicon semiconductor or an oxide semiconductor with ions.

The gate insulating layer 130 may be disposed on the active layer ACT. The gate insulating layer 130 may include an inorganic layer, for example, a silicon nitride layer, a silicon oxynitride layer, a silicon oxide layer, a titanium oxide layer, or an aluminum oxide layer.

The first gate metal layer GTL1 may be disposed on the gate insulating layer 130. The first gate metal layer GTL1 may include the gate electrode TG of each of the thin-film transistors TFT and first capacitor electrodes CAE1. The first gate metal layer GTL1 may be a single layer or a multilayer including any one or more of, for example, molybdenum (Mo), aluminum (Al), chromium (Cr), gold (Au), titanium (Ti), nickel (Ni), neodymium (Nd), copper (Cu), and alloys thereof.

The first interlayer insulating film 141 may be disposed on the first gate metal layer GTL1. The first interlayer insulating film 141 may include an inorganic layer such as, for example, a silicon nitride layer, a silicon oxynitride layer, a silicon oxide layer, a titanium oxide layer, or an aluminum oxide layer.

The second gate metal layer GTL2 may be disposed on the first interlayer insulating film 141. The second gate metal layer GTL2 may include second capacitor electrodes CAE2. The second capacitor electrodes CAE2 may overlap the first capacitor electrodes CAE1 in the third direction (e.g., the Z-axis direction). Each capacitor Cst may include a first capacitor electrode CAE1 and a second capacitor electrode CAE2. The second gate metal layer GTL2 may be a single layer or a multilayer including any one or more of, for example, molybdenum (Mo), aluminum (Al), chromium (Cr), gold (Au), titanium (Ti), nickel (Ni), neodymium (Nd), copper (Cu), and alloys thereof.

The second interlayer insulating film 142 may be disposed on the second gate metal layer GTL2. The second interlayer insulating film 142 may include an inorganic layer such as, for example, a silicon nitride layer, a silicon oxynitride layer, a silicon oxide layer, a titanium oxide layer, or an aluminum oxide layer.

The first data metal layer DTL1 including first connection electrodes CE1 may be disposed on the second interlayer insulating film 142. Each of the first connection electrodes CE1 may be connected to the first electrode TS or the second electrode TD of a thin-film transistor TFT through a first contact hole CT1 which penetrates the gate insulating layer 130, the first interlayer insulating film 141, and the second interlayer insulating film 142. The first data metal layer DTL1 may be a single layer or a multilayer including any one or more of, for example, molybdenum (Mo), aluminum (Al), chromium (Cr), gold (Au), titanium (Ti), nickel (Ni), neodymium (Nd), copper (Cu), and alloys thereof.

The first planarization layer 160 may be disposed on the first data metal layer DTL1 to planarize steps caused by the active layer ACT, the first gate metal layer GTL1, the second gate metal layer GTL2, and the first data metal layer DTL1. The first planarization layer 160 may include an organic layer such as, for example, acryl resin, epoxy resin, phenolic resin, polyamide resin, or polyimide resin.

The second data metal layer DTL2 may be disposed on the first planarization layer 160. The second data metal layer DTL2 may include second connection electrodes CE2. Each of the second connection electrodes CE2 may be connected to a first connection electrode CE1 through a second contact hole CT2 which penetrates the first planarization layer 160. The second data metal layer DTL2 may be a single layer or a multilayer including any one or more of, for example, molybdenum (Mo), aluminum (Al), chromium (Cr), gold (Au), titanium (Ti), nickel (Ni), neodymium (Nd), copper (Cu), and alloys thereof.

The second planarization layer 180 may be disposed on the second data metal layer DTL2. The second planarization layer 180 may include an organic layer such as, for example, acryl resin, epoxy resin, phenolic resin, polyamide resin, or polyimide resin.

The light emitting element layer EML may be disposed on the second planarization layer 180. The light emitting element layer EML may include a plurality of light emitting elements LEL and a pixel defining layer 190. Each of the light emitting elements LEL may be, but is not limited to, an organic light emitting diode element including a pixel electrode 171, a light emitting layer 172, and a common electrode 173.

The pixel electrode 171 may be disposed on the second planarization layer 180. The pixel electrode 171 may be connected to a second connection electrode CE2 through a third contact hole CT3 which penetrates the second planarization layer 180.

In a top emission structure in which light is emitted in a direction from the light emitting layer 172 toward the common electrode 173, the pixel electrode 171 may include a metal material having high reflectivity, such as, for example, a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer 190 may be disposed on the second planarization layer 180 to cover edges of each of the pixel electrodes 171 in order to define a plurality of emission areas EA1, EA2 and EA3. The pixel defining layer 190 may include an organic layer such as, for example, acryl resin, epoxy resin, phenolic resin, polyamide resin, or polyimide resin.

Each of the emission areas EA1, EA2 and EA3 is an area in which the pixel electrode 171, the light emitting layer 172, and the common electrode 173 are sequentially stacked so that holes from the pixel electrode 171 and electrons from the common electrode 173 are recombined with each other in the light emitting layer 172 to emit light.

The light emitting layer 172 may be disposed on the pixel electrode 171. The light emitting layer 172 may include an organic material to emit light of a selected color. For example, the light emitting layer 172 may include a hole transporting layer, an organic material layer, and an electron transporting layer.

The common electrode 173 may be disposed on the light emitting layer 172. The common electrode 173 may cover the light emitting layer 172. The common electrode 173 may be a common layer formed in common in the emission areas EA1, EA2 and EA3. A capping layer may be formed on the common electrode 173.

In the top emission structure, the common electrode 173 may include a transparent conductive material (TCO) that can transmit light, such as, for example, indium tin oxide (ITO) or indium zinc oxide (IZO), or may include a semi-transmissive conductive material such as, for example, magnesium (Mg), silver (Ag) or an alloy of Mg and Ag. When the common electrode 173 includes a semi-transmissive conductive material, light output efficiency may be increased by a microcavity.

Spacers 191 may be disposed on the pixel defining layer 190. The spacers 191 may support a mask during a process of forming the light emitting layers 172. The spacers 191 may include an organic layer such as, for example, acryl resin, epoxy resin, phenolic resin, polyamide resin, or polyimide resin.

The encapsulation layer TFE may be disposed on the common electrode 173. The encapsulation layer TFE may include at least one inorganic layer that prevents oxygen or moisture from penetrating into the light emitting element layer EML. In addition, the encapsulation layer TFE may include at least one organic layer that protects the light emitting element layer EML from foreign substances such as dust. For example, the encapsulation layer TFE may include a first encapsulating inorganic layer TFE1, an encapsulating organic layer TFE2, and a second encapsulating inorganic layer TFE3.

The first encapsulating inorganic layer TFE1 may be disposed on the common electrode 173, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer in which one or more inorganic layers selected from a silicon nitride layer, a silicon oxynitride layer, a silicon oxide layer, a titanium oxide layer, and an aluminum oxide layer are alternately stacked. The encapsulating organic layer TFE2 may be an organic layer such as, for example, acryl resin, epoxy resin, phenolic resin, polyamide resin, or polyimide resin.

As illustrated, a third emission area EA3 may be larger than a first emission area EA1, and the first emission area EA1 may be larger than a second emission area EA2. Here, the first emission area EA1 may be a red light-emitting area, the second emission area EA2 may be a green light-emitting area, and the third emission area EA3 may be a blue light-emitting area. However, embodiments of the present disclosure are not limited to the relative sizes of the emission areas.

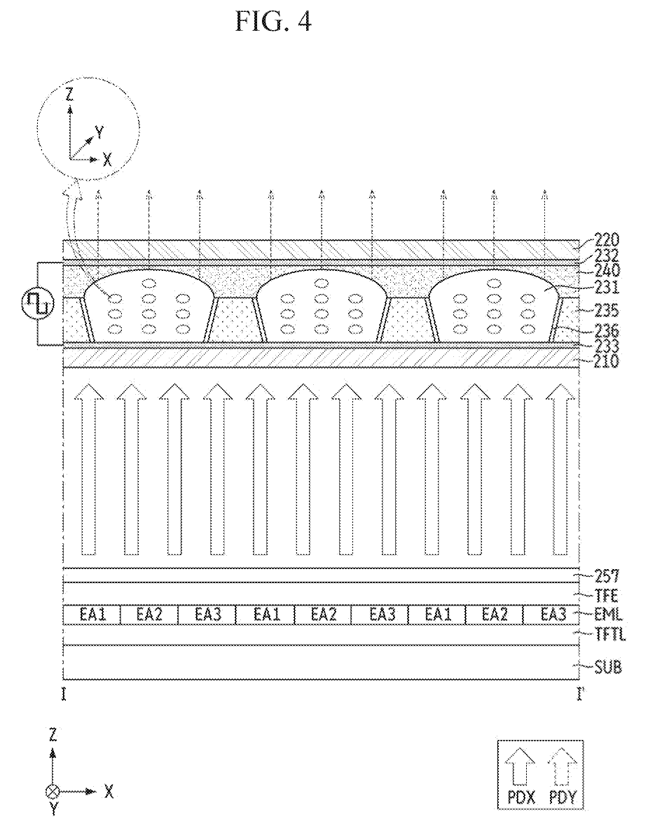

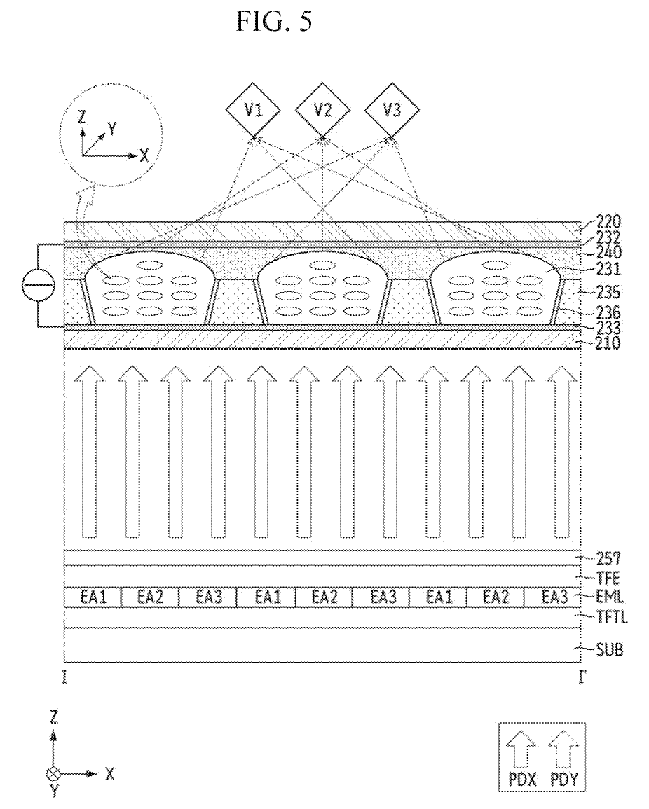

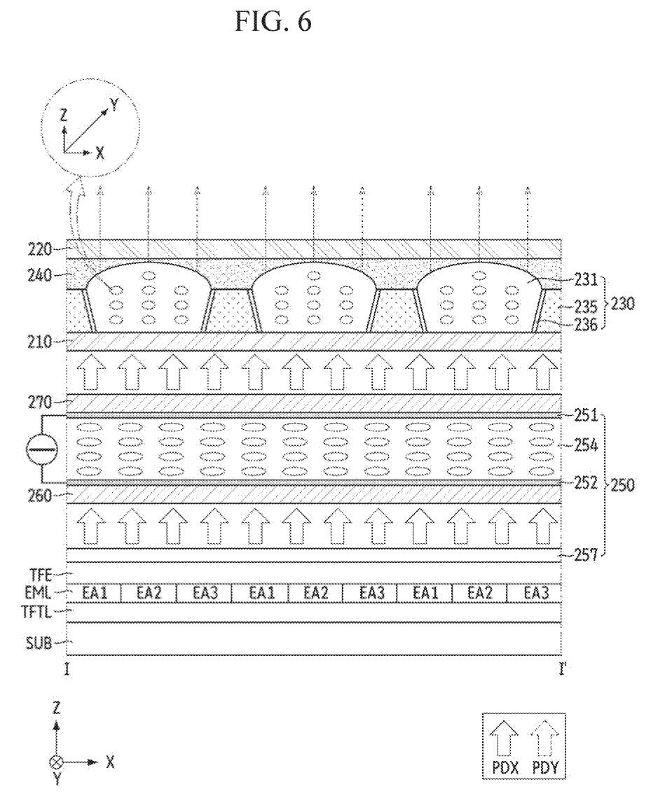

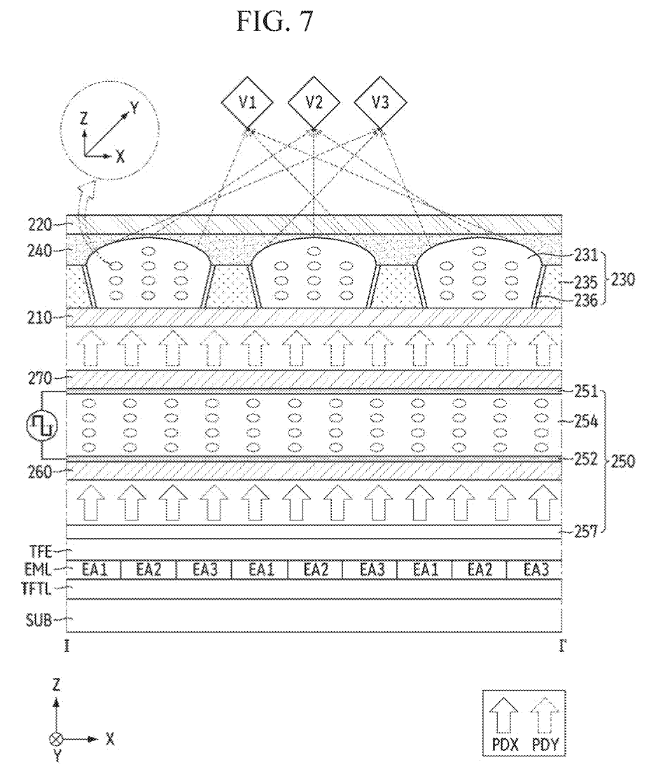

FIG. 4 is a cross-sectional view of a first type of light field display in which a 2D image is realized. FIG. 5 is a cross-sectional view of a first type of light field display in which a 3D image is realized. FIG. 6 is a cross-sectional view of a second type of light field display in which a 2D image is realized. FIG. 7 is a cross-sectional view of a second type of light field display in which a 3D image is realized.

In a light field display, an optical member is disposed in front of a display module as described above, so that different image information is shown to both eyes of a viewer. The light field display may realize a 2D image or a 3D image.

Specific content may include all things existing in the real world, such as, for example, text, pictures and objects, as well as all things realized as digital data and not existing in the real world. The specific content may be collected at a first viewing angle to produce first data. The specific content may be collected at a second viewing angle to produce second data. In addition, when the specific content is collected at an n^{th} viewing angle, n^{th} data may be produced.

A display device according to an embodiment may include a display panel in which a plurality of light emitting elements are arranged and an optical member which is disposed on the display panel. Light emitted from a light emitting element disposed in the display panel may or may not be refracted while passing through the optical member, depending on whether a 3D image is to be realized. For example, when a 3D image is to be realized, light emitted from a light emitting element may be refracted by the optical member. For example, when a 2D image is to be realized, light emitted from a light emitting element may not be refracted by the optical member.

However, even when a 2D image is to be realized, light emitted from a light emitting element may be refracted. In this case, the resolution of the display device may be reduced.

A viewing angle may be assigned to each of the light emitting elements by adjusting a direction in which light emitted from the light emitting elements is refracted. This may be referred to as viewing angle mapping. The pitch, tilt angle, etc. of a lens (e.g., a slanted lens) included in the optical member may be adjusted to control the direction of light emitted from the light emitting elements.

A specific viewing angle may be mapped to each of the light emitting elements, and light emitted from the mapped light emitting element may travel in the assigned viewing angle direction. For example, light emitted from a light emitting element to which the first viewing angle is mapped may travel in a first viewing angle direction in which a first view area is disposed, and light emitted from a light emitting element to which the second viewing angle is mapped may travel in a second viewing angle direction in which a second view area is disposed.

The first data produced by collecting specific content at the first viewing angle may be input to the light emitting element to which the first viewing angle is mapped. The second data may be input to the light emitting element to which the second viewing angle is mapped.

The first viewing angle may be disposed on a side (e.g., a left-eye side) of a midpoint between both eyes of a user. The second viewing angle may be disposed on the other side (e.g., a right-eye side) of the midpoint between both eyes of the user.

Regardless of which viewing angle is mapped, if different images are perceived by left and right eyes of a user, respectively, the user may feel that a 3D image is realized from the display device. If the same image is perceived by the left and right eyes of the user, the user may feel that a 2D image is realized from the display device. The case in which the same image is perceived by the left and right eyes of the user may be when light emitted from the display panel is not refracted. However, as described above, even if light emitted from the display panel is refracted, the same image may be perceived by the left and right eyes of the user. In this case, the resolution of the display device may be reduced.

Therefore, a user may feel a 3D image from an image realized by inputting the first data to the light emitting element to which the first viewing angle is mapped and inputting the second data to the light emitting element to which the second viewing angle is mapped.

On the other hand, a user may feel a 2D image from an image realized by inputting the first data to both the light emitting element to which the first viewing angle is mapped and the light emitting element to which the second viewing angle is mapped. Light emitted from the light emitting element to which the first viewing angle is mapped is still refracted even when a 2D image is realized, and light emitted from the light emitting element to which the second viewing angle is mapped is also still refracted.

A 2D image may be realized when light emitted from a light emitting element is not refracted by the optical member. In this case, a user may feel a 2D image because the light emitted from the light emitting element is not refracted regardless of the viewing angle mapped to the light emitting element. The resolution of the 2D image realized thus may be relatively higher than the resolution of a 2D image realized when the same image is perceived by left and right eyes of a user even though light is refracted.

That is, a 2D image may be realized when light emitted from a light emitting element is not refracted by the optical member or when the same data is input to both eyes of a user even if the light is refracted. In addition, the resolution may be different in each case.

Light field displays may include a switchable display which can determine whether to realize a 2D image or a 3D image by controlling whether to refract light emitted from a display panel and a non-switchable display which always refracts light emitted from a display panel. Even in the non-switchable display in which light emitted from the display panel is always refracted, a 2D image may be realized if the same data is input regardless of the viewing angle mapped to a light emitting element as described above. When a 2D image is realized in the non-switchable display, resolution may be reduced.

The switchable display may determine whether to realize a 2D image or a 3D image by controlling a linear polarization direction of light emitted from the display panel and utilizing the refractive index anisotropy of a lens included in an optical lens unit.

For example, light emitted from the display panel may pass through a polarizing member disposed on the display panel and may exit along a path in a first linear polarization direction.

In an embodiment, a minor-axis direction of a lens included in the optical lens unit may coincide with the first linear polarization direction. A major-axis direction of the lens may coincide with a second linear polarization direction.

The optical lens unit may further include a filler layer disposed on a plurality of lenses. The lenses may have birefringence characteristics. For example, a refractive index of a lens in the minor-axis direction may be equal to a refractive index of the filler layer, and a refractive index of the lens in the major-axis direction may be greater than the refractive index of the filler layer. However, embodiments of the present disclosure are not limited to this example.

In the above case, if a voltage is applied to the lens, the minor-axis direction of the lens may be parallel to a path in the first linear polarization direction. When light having a path in the first linear polarization direction and emitted from the display panel passes through the lens, the light may experience the refractive index in the minor-axis direction which coincides with the first linear polarization direction. Since the refractive index of the lens in the minor-axis direction is about equal to the refractive index of the filler layer, the light passing through the lens may travel straight without being refracted at an interface between the lens and the filler layer. In this case, since the light is not refracted, the light perceived by both eyes of a user may be straight light, and the user may feel that a 2D image is realized. This mechanism may be applied to a first type of light field display in which a 2D image is realized (see FIG. 4).

In the above case, if no voltage is applied to the lens, the major-axis direction of the lens may be parallel to a path in the first linear polarization direction. When light having a path in the first linear polarization direction and emitted from the display panel passes through the lens, the light may experience the refractive index in the major-axis direction which coincides with the first linear polarization direction. Since the refractive index of the lens in the major-axis direction is greater than the refractive index of the filler layer, the light passing through the lens may be refracted at the interface between the lens and the filler layer. In this case, since the light is refracted, the light perceived by both eyes of a user may be refracted light, and the user may feel that a 3D image is realized. This mechanism may be applied to a first type of light field display in which a 3D image is realized (see FIG. 5).

In a second type of light field display, no voltage may be applied to the lens, and the minor-axis direction and the major-axis direction of the lens may be fixed to be parallel to the first linear polarization direction and the second linear polarization direction, respectively (see FIGS. 6 and 7). Instead, light having a path in the first linear polarization direction and emitted from the display panel may pass through driving liquid crystals disposed between driving electrodes. The light passing through the driving liquid crystals to which no voltage is applied may pass through the driving liquid crystals while maintaining the path in the first linear polarization direction (see FIG. 6). The light passing through the driving liquid crystals to which a voltage is applied may pass through the driving liquid crystals while switching from the path in the first linear polarization direction to a path in the second linear polarization direction (see FIG. 7).

Since the minor-axis direction and the major-axis direction of the lens are parallel to the first linear polarization direction and the second linear polarization direction, respectively, if the light passing through the driving liquid crystals has the path in the first linear polarization direction, the light may experience the refractive index of the lens in the minor-axis direction. If the light passing through the driving liquid crystals has the path in the second linear polarization direction, the light may experience the refractive index of the lens in the major-axis direction. The refractive index of the lens in the minor-axis direction is equal to the refractive index of the filler layer, and the refractive index of the lens in the major-axis direction is greater than the refractive index of the filler layer. Therefore, whether the light passing through the driving liquid crystals will be refracted at the interface between the lens and the filler layer may be determined by the linear polarization direction of the light passing through the driving liquid crystals.

As described above, switchable light field displays may include a first type of light field display (see FIGS. 4 and 5) and a second type of light field display (see FIGS. 6 and 7).

In the first type of light field display, the linear polarization direction of light passing through a display panel is not changed as described above. Instead, the first type of light field display may directly change the major-axis direction and the minor-axis direction of a lens having birefringence characteristics. A changed axial direction may coincide with the linear polarization direction of the light passing through the display panel, and the light may pass through an interface while experiencing a refractive index in the changed axial direction.

In the second type of light field display, the linear polarization direction of light passing through a display panel may be changed as the light passes through driving liquid crystals. Instead, the second type of light field display cannot directly change the major- and minor-axis directions of a lens having birefringence characteristics. Therefore, the linear polarization direction of the light passing through the driving liquid crystals may coincide with a fixed axial direction of the lens, and the light may pass through an interface while experiencing a refractive index in the fixed axial direction.

Referring to FIGS. 6 and 7, in the second type of light field display, the display panel may include a substrate SUB, a thin-film transistor layer TFTL, a light emitting element layer EML, and an encapsulation layer TFE.

The substrate SUB may have rigidity to support elements formed on the substrate SUB. For example, the substrate SUB may be a glass substrate or a plastic substrate such as polyethylene terephthalate (PET).

The thin-film transistor layer TFTL may be disposed on the substrate SUB. The thin-film transistor layer TFTL may control the brightness of the display device 290. The thin-film transistor layer TFTL may include transistors.

The light emitting element layer EML may be disposed on the thin-film transistor layer TFTL. The light emitting element layer EML may include first through third emission areas EA1 through EA3. The first through third emission areas EA1 through EA3 may be alternately arranged.

The encapsulation layer TFE may be disposed on the light emitting element layer EML. The encapsulation layer TFE may include at least one inorganic layer and at least one organic layer to encapsulate the light emitting element layer EML.

An optical member may include an optical lens unit disposed between a first base substrate 210 and a second base substrate 220. The optical lens unit may include a plurality of lenses 231 and a black matrix 235, light reflectors 236, etc. disposed between the lenses 231. The optical member may include a filler layer 240 disposed between the first base substrate 210 and the second base substrate 220. Although the filler layer 240 is illustrated as being disposed on the optical lens unit, embodiments of the present disclosure are not limited to this case. For example, light passing through the display panel may also pass through the filler layer 240 first and then pass through the optical lens unit. In addition, although the lenses 231 in the optical lens unit are convex in the third direction (e.g., the Z-axis direction), embodiments of the present disclosure are not limited to this case.

As described above, a refractive index range of a material having refractive index anisotropy in the lenses 231 and a refractive index value of the filler layer 240 are adjusted, and then whether light is to be refracted is determined based on the presence or absence of a difference in refractive index. Therefore, the vertical relationship between the optical lens unit and the filler layer 240, the convex direction of the lenses 231, etc. are within a range that can be simply designed and modified by those of ordinary skill in the art according to embodiments.

The first base substrate 210, the second base substrate 220, a third base substrate 260, and a fourth base substrate 270 may include a material that can transmit light, such as glass or plastic.

A polarization control unit 250 may be formed behind the first base substrate 210 or in front of the display panel in order to switch 2D image display light of the display panel to a path PDX or PDY in the first linear polarization direction or the second linear polarization direction and output the 2D image display light along the path PDX or PDY in the first linear polarization direction or the second linear polarization direction. The polarization control unit 250 may include a first driving electrode 251, a second driving electrode 252, and driving liquid crystals 254 disposed between the first driving electrode 251 and the second driving electrode 252. The polarization control unit 250 may further include a polarizing member 257 disposed on the display panel.

The polarization control unit 250 may control light, which is incident along a path PDX in the first linear polarization direction through the polarizing member 257, to pass through the polarization control unit 250 along the path PDX in the first linear polarization direction or may switch the light to a path PDY in the second linear polarization direction and control the light to pass through the polarization control unit 250 along the path PDY in the second linear polarization direction.

The polarization control unit 250 may also switch light, which is incident along a path PDX in the first linear polarization direction through the polarizing member 257, to a path in an arbitrary linear polarization direction between the first linear polarization direction and the second linear polarization direction and may control the light to pass through the polarization control unit 250 along the path in the arbitrary linear polarization direction.

For example, the first linear polarization direction may be parallel to the first direction (e.g., the X-axis direction), and the second linear polarization direction may be parallel to the second direction (e.g., the Y-axis direction), but embodiments of the present disclosure are not limited to this example.

At least some elements (251, 252, 254) of the polarization control unit 250 may be disposed between the third base substrate 260 and the fourth base substrate 270. The polarizing member 257 of the polarization control unit 250 may be disposed between the display panel and the third base substrate 260.

The first driving electrode 251 may be disposed between the third base substrate 260 and the fourth base substrate 270. A voltage may be applied to the first driving electrode 251.

The second driving electrode 252 may be disposed between the third base substrate 260 and the first driving electrode 251. The second driving electrode 252 may be parallel to the first driving electrode 251. The shape of the second driving electrode 252 may correspond to the shape of the first driving electrode 251. A voltage may be applied to the second driving electrode 252. The driving liquid crystals 254 may control the linear polarization direction of light by a difference between the voltage applied to the first driving electrode 251 and the voltage applied to the second driving electrode 252.

The polarizing member 257 may be disposed between the display panel and the third base substrate 260. Light emitted from the display panel may vibrate in all directions. The polarizing member 257 may transmit only light vibrating in a specific direction among the light emitted from the display panel and may block the rest. In an embodiment, the polarizing member 257 may transmit only light having a path PDX in the first linear polarization direction among the light emitted from the display panel, but embodiments of the present disclosure are not limited to this case.

The driving liquid crystals 254 may be disposed between the first driving electrode 251 and the second driving electrode 252. The driving liquid crystals 254 may include liquid crystals which are birefringent materials. The arrangement of the driving liquid crystals 254 may vary according to the difference between the voltages applied to the first driving electrode 251 and the second driving electrode 252. The driving liquid crystals 254 may be twisted nematic (TN) liquid crystals.

Referring to FIG. 6, the difference between the voltage applied to the first driving electrode 251 and the voltage applied to the second driving electrode 252 during a 2D image display period may be less than a selected value. The driving liquid crystals 254 may maintain the linear polarization direction of incident light having a path PDX in the first linear polarization direction. The light passing through the driving liquid crystals 254 may still have the path PDX in the first linear polarization direction.

Referring to FIG. 7, the difference between the voltage applied to the first driving electrode 251 and the voltage applied to the second driving electrode 252 during a 3D image display period may be about equal to or greater than the selected value. The driving liquid crystals 254 may change the linear polarization direction of incident light having a path PDX in the first linear polarization direction. The light passing through the driving liquid crystals 254 may have a path PDY in the second linear polarization direction.

Referring again to FIGS. 6 and 7, the first base substrate 210, the second base substrate 220, and the optical lens unit disposed between the first base substrate 210 and the second base substrate 220 may be disposed on the fourth base substrate 270. The optical lens unit may be formed in the form of a lens sheet including lenses arranged side by side. The polarization control unit 250 may be stacked and overlapped with the optical lens unit which is formed in the form of a lens sheet.

The optical lens unit may include the lenses 231, the black matrix 235, and the light reflectors 236.

Light passing through the lenses 231 may experience a refractive index of the lenses 231 in the major-axis direction, a refractive index in the minor-axis direction, or countless refractive indices in directions between the major axis and the minor axis, depending on the arrangement of birefringent materials (e.g., liquid crystals or slits) included in the lenses 231. The countless refractive indices in the directions between the major axis and the minor axis of each of the lenses 231 may be smaller than the refractive index in the major-axis direction and greater than the refractive index in the minor-axis direction, but embodiments of the present disclosure are not limited to this case. For example, the countless refractive indices in the directions between the major axis and the minor axis of each of the lenses 231 may also be smaller than the refractive index in the minor-axis direction and greater than the refractive index in the major-axis direction.

In an embodiment, the major-axis direction of the lenses 231 may be parallel to the second direction (e.g., the Y-axis direction), and the minor-axis direction of the lenses 231 may be parallel to the first direction (e.g., the X-axis direction). In addition, the refractive index of the filler layer 240 disposed on the lenses 231 may be about equal to the refractive index of the lenses 231 in the minor-axis direction and may be smaller than the refractive index of the lenses 231 in the major-axis direction, but embodiments of the present disclosure are not limited to this case.

Referring to FIG. 6, light passing through the driving liquid crystals 254 may have a path PDX in the first linear polarization direction, and the first linear polarization direction may be coincident with or parallel to the first direction (e.g., the X-axis direction). Therefore, the light passing through the driving liquid crystals 254 may experience the refractive index of the lenses 231 in the minor-axis direction. Since the refractive index of the lenses 231 in the minor-axis direction is about equal to the refractive index of the filler layer 240, the light passing through the driving liquid crystals 254 may travel straight without being refracted at interfaces between the lenses 231 and the filler layer 240. A 2D image may be realized from the second type of light field display by the un-refracted light.

Referring to FIG. 7, light passing through the driving liquid crystals 254 may have a path PDY in the second linear polarization direction, and the second linear polarization direction may be coincident with or parallel to the second direction (e.g., the Y-axis direction). Therefore, the light passing through the driving liquid crystals 254 may experience the refractive index of the lenses 231 in the major-axis direction. Since the refractive index of the lenses 231 in the major-axis direction is greater than the refractive index of the filler layer 240, the light passing through the driving liquid crystals 254 may be refracted at the interfaces between the lenses 231 and the filler layer 240. A 3D image may be realized from the second type of light field display by the refracted light. The refracted light may travel to a first view area V1, a second view area V2, and a third view area V3 according to mapped viewing angles.

Referring again to FIGS. 6 and 7, the black matrix 235 may be disposed between the lenses 231. The black matrix 235 may include a light absorbing material that absorbs light. For example, the light absorbing material may be a black dye or a black pigment. The black matrix 235 may absorb light between the lenses 231. Accordingly, the black matrix 235 may prevent crosstalk from occurring due to diffraction of light at the boundary between the lenses 231.

In plan view, a length of a lower surface of the black matrix 235 may be greater than a length of an upper surface of the black matrix 235. Side surfaces of the black matrix 235 may be formed as planes. That is, the black matrix 235 may be formed in a trapezoidal shape.

The light reflectors 236 may be disposed between the lenses 231 and the black matrix 235 to reflect light traveling from the emission areas EA1, EA2 and EA3 toward the black matrix 235.

The filler layer 240 may be disposed on the lenses 231, the black matrix 235, and the light reflectors 236. The second base substrate 220 may be disposed on the filler layer 240.

The filler layer 240 may include a transparent material that can transmit light. For example, the filler layer 240 may include an isotropic polymer material.

As described above, the refractive index of the filler layer 240 may be about equal to the refractive index of liquid crystals in the lenses 231 in the minor-axis direction. The refractive index of the filler layer 240 may be smaller than the refractive index of the liquid crystals in the lenses 231 in the major-axis direction. Accordingly, light passing through the lenses 231 may or may not be refracted at the interfaces.

Referring to FIGS. 4 and 5, in the first type of light field display, the display panel may include a substrate SUB, a thin-film transistor layer TFTL, a light emitting element layer EML, and an encapsulation layer TFE. Elements having substantially the same functions as those of the second type of light field display described above are indicated by like reference characters, and a repeated description thereof will be omitted.

A polarizing member 257 may be disposed between the display panel and a first base substrate 210. Light emitted from the display panel may vibrate in all directions. The polarizing member 257 may transmit only light vibrating in a specific direction among the light emitted from the display panel and may block the rest. In an embodiment, the polarizing member 257 may transmit only light having a path PDX in the first linear polarization direction among the light emitted from the display panel, but embodiments of the present disclosure are not limited to this case.

A third driving electrode 232 may be disposed between the first base substrate 210 and a second base substrate 220, and a fourth driving electrode 233 may be disposed between the first base substrate 210 and the third driving electrode 232. An optical lens unit, which includes lenses 231, a black matrix 235 and light reflectors 236, may be disposed between the third driving electrode 232 and the fourth driving electrode 233. A filler layer 240 may be disposed on the optical lens unit, but as described above, the vertical relationship between them is not limited to that illustrated in the drawings.

Voltages may be applied to the third driving electrode 232 and the fourth driving electrode 233, and the lenses 231 may include liquid crystals which are birefringent materials. The arrangement of the liquid crystals in the lenses 231 may vary according to a difference between the voltages applied to the third driving electrode 232 and the fourth driving electrode 233.

Referring to FIG. 4, the difference between the voltage applied to the third driving electrode 232 and the voltage applied to the fourth driving electrode 233 during a 2D image display period may be about equal to or greater than a selected value. Light passing through the display panel may have a path PDX in the first linear polarization direction. The first linear polarization direction may be coincident with or parallel to the minor-axis direction of the liquid crystals in the lenses 231. The light may pass through the liquid crystals while experiencing a refractive index of the liquid crystals in the minor-axis direction. Since the refractive index in the minor-axis direction is equal to a refractive index of the filler layer 240, the light may not be refracted at interfaces. A 2D image may be realized from the first type of light field display by the un-refracted light.

Referring to FIG. 5, the difference between the voltage applied to the third driving electrode 232 and the voltage applied to the fourth driving electrode 233 during a 3D image display period may be less than the selected value. Light passing through the display panel may have a path PDX in the first linear polarization direction. The first linear polarization direction may be coincident with or parallel to the major-axis direction of the liquid crystals in the lenses 231. The light may pass through the liquid crystals while experiencing a refractive index of the liquid crystals in the major-axis direction. Since the refractive index in the major-axis direction is greater than the refractive index of the filler layer 240, the light may be refracted at the interfaces. A 3D image may be realized from the first type of light field display by the refracted light. The refracted light may travel to a first view area V1, a second view area V2, and a third view area V3 according to mapped viewing angles.

In the above description, it is assumed that the refractive index of the filler layer 240 is about equal to the refractive index of the lenses 231 or the liquid crystals in the lenses 231 in the minor-axis direction and is smaller than the refractive index in the major-axis direction. In addition, it is assumed that linear polarization directions are specified in the first and second types of light field displays. In addition, it is assumed that in the first type of light field display, a 2D image is realized when voltages are applied to the third driving electrode 232 and the fourth driving electrode 233, and a 3D image is realized when no voltage is applied. In addition, it is assumed that in the second type of light field display, a 2D image is realized when no voltage is applied to the first driving electrode 251 and the second driving electrode 252, and a 3D image is realized when voltages are applied.

However, this is only an example used for ease and consistency of description, and variables, such as a refractive index range based on the birefringence characteristics of liquid crystals, the refractive index value of the filler layer, and the linear polarization direction of light passing through an individual element, can be freely and simply designed and modified within the scope of practice of those of ordinary skill in the art.

However, in the first type of light field display, the major-axis direction and the minor-axis direction of the liquid crystals in the lenses 231 may be directly changed. In the second type of light field display, the linear polarization direction of light passing through the display panel may be directly changed.

As described above, a 2D image may be realized when light emitted from a display panel travels straight without being refracted. However, even if the light is refracted, the 2D image may also be realized when the same image is perceived by both eyes of a user. When the 2D image is realized because the same image is perceived by both eyes of the user even though the light refracted, the light may travel to a view area (or a viewing angle) assigned or mapped to a plurality of light emitting elements. This may cause the problem of resolution reduction.

A display device according to an embodiment of the present disclosure can eliminate or mitigate such resolution reduction that may occur in an area where a 2D image is realized when both a 2D image and a 3D image are realized in one display device. Therefore, the display quality of the display device can be improved.

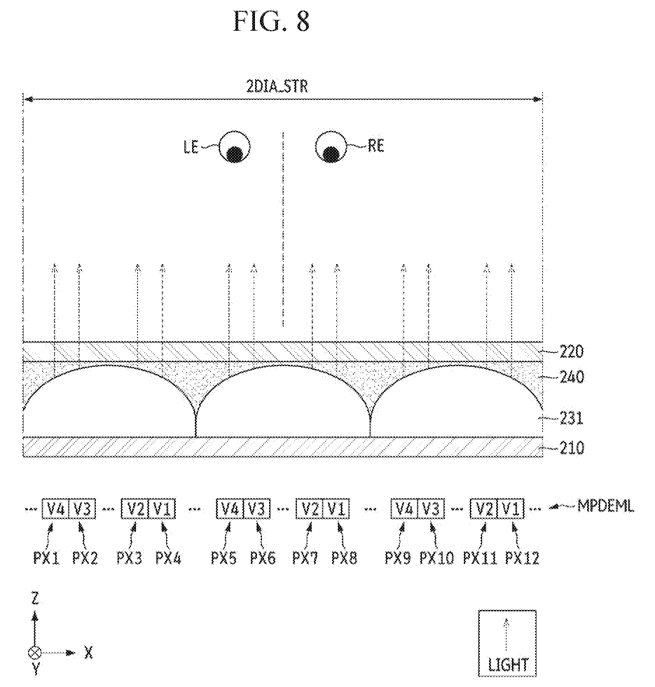

FIG. 8 is a cross-sectional view illustrating a case in which a 2D image is realized in an area where light is not refracted.

Referring to FIG. 8, light field displays may include a switchable display and a non-switchable display as described above. The non-switchable display cannot change whether light is refracted, and light emitted from a display panel may be always refracted. The switchable display can determine whether light is refracted, and light emitted from a display panel may or may not be refracted.

A display device according to an embodiment may include a non-refractive area 2DIA_STR. The display device may include a light emitting element layer MPDEML including light emitting elements disposed in first through twelfth pixels PX1 through PX12, respectively. Each of the first through twelfth pixels PX1 through PX12 may include a first subpixel which realizes a first color, a second subpixel which realizes a second color, and a third subpixel which realizes a third color. The first color, the second color, and the third color may each be selected from red, green, and blue such that they do not overlap each other. For example, the first color may be red, the second color may be green, and the third color may be blue, but embodiments of the present disclosure are not limited to this example.

The non-refractive area 2DIA_STR may be formed when a refractive index experienced by light passing through lenses 231 is about equal to a refractive index of a filler layer 240 in a switchable display device according to an embodiment. The switchable display device according to an embodiment may include not only the non-refractive area 2DIA_STR, but also a first refractive area 3DIA_REF and a second refractive area 2DIA_REF, which will be described further below. In a display device according to an embodiment, including a first type of light field display and a second type of light field display, the non-refractive area 2DIA_STR and a refractive area may be switched with each other depending on whether a voltage is applied. The refractive area may be the first refractive area 3DIA_REF in which a 3D image is realized or the second refractive area 2DIA_REF in which a 2D image is realized. The non-refractive area 2DIA_STR may not be formed in the non-switchable display device.

Both eyes LE and RE of a user may perceive light that travels straight without being refracted. Image data perceived by the user’s left eye LE and image data perceived by the user’s right eye RE may be the same. The user may feel that a 2D image is realized from the display device.

The user’s right eye RE may perceive all light emitted from the first through twelfth pixels PX1 through PX12. The user’s left eye LE may also perceive all light emitted from the first through twelfth pixels PX1 through PX12. Each of the right eye RE and the left eye LE of the user may feel all light emitted from the twelve pixels. In this case, the resolution perceived by the user looking at the non-refractive area 2DIA_STR may be relatively high.

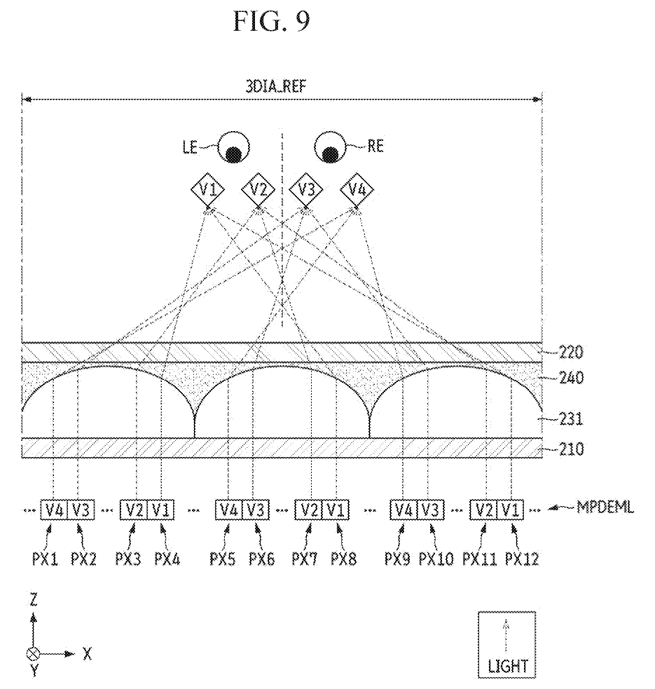

FIG. 9 is a cross-sectional view illustrating a case in which a 3D image is realized in an area where light is refracted.

Referring to FIG. 9, a display device according to an embodiment may include a refractive area including a first refractive area 3DIA_REF.

The refractive area may be formed when a refractive index experienced by light passing through lenses 231 is different from a refractive index of a filler layer 240 in a switchable display device according to an embodiment. In the switchable display device according to an embodiment, the refractive area may appear selectively depending on whether a voltage is applied. In a non-switchable display device according to an embodiment, the refractive area may always appear.

Both eyes LE and RE of a user may perceive refracted light. The user who perceives light emitted from the first refractive area 3DIA_REF may feel that a 3D image is realized from the first refractive area 3DIA_REF. In this case, image data perceived by the user’s left eye LE and image data perceived by the user’s right eye RE may be different. The user may feel that a 3D image is realized from the display device.

Specific view areas (or viewing angles or viewing angle areas) may be assigned (or mapped) to first through twelfth pixels PX1 through PX12, respectively. For example, a fourth view area V4 may be mapped to the first pixel PX1, a third view area V3 may be mapped to the second pixel PX2, a second view area V2 may be mapped to the third pixel PX3, and a fourth view area V4 may be mapped to the fourth pixel PX4. View areas may also be mapped to the fifth through twelfth pixels PX5 through PX12 as illustrated in the drawing.

Light emitted from the first refractive area 3DIA_REF may be refracted. Light emitted from the display device according to an embodiment may travel to the first view area V1, the second view area V2, the third view area V3, and the fourth view area V4. However, the number of view areas is not limited to this example.

The third view area V3 and the fourth view area V4 may be disposed on the right eye side RE of the user, and the first view area V1 and the second view area V2 may be disposed on the left eye side LE of the user. Light emitted from pixels (PX1, PX2, PX5, PX6, PX9, PX10) to which the third view area V3 and the fourth view area V4 are assigned may be refracted by the lenses 231 toward where the user’s right eye RE is disposed. Light emitted from pixels (PX3, PX4, PX7, PX8, PX11, PX12) to which the first view area V1 and the second view area V2 are assigned may be refracted by the lenses 231 toward where the user’s left eye LE is disposed.

Therefore, the user’s right eye RE may not perceive light emitted from the pixels (PX3, PX4, PX7, PX8, PX11, PX12) to which the first view area V1 and the second view area V2 are assigned.

In addition, the user’s left eye LE may not perceive light emitted from the pixels (PX1, PX2, PX5, PX6, PX9, PX10) to which the third view area V3 and the fourth view area V4 are assigned.

As described above, although all pixels arranged in a display panel emit light, each of the left eye LE and the right eye RE of the user may not perceive light emitted from pixels to which specific view areas are assigned. Accordingly, each of the right eye RE and the left eye LE of the user may not perceive at least a portion of the light emitted from the twelve pixels. In this case, the resolution perceived by the user looking at the first refractive area 3DIA_REF may be relatively low. This will be described in further detail below.

The first view area V1 may form a first viewing angle. The second view area V2 may form a second viewing angle. The third view area V3 may form a third viewing angle. The fourth view area V4 may form a fourth viewing angle. Light emitted from the first refractive area 3DIA_REF may form all of the first through fourth viewing angles.

First data generated by collecting specific content at the first viewing angle, second data generated by collecting the specific content at the second viewing angle, third data generated by collecting the specific content at the third viewing angle, and fourth data generated by collecting the specific content at the fourth viewing angle may be obtained. An image data voltage formed from the first data, an image data voltage formed from the second data, an image data voltage formed from the third data, and an image data voltage formed from the fourth data may be different from each other.

The image data voltages formed from the first data through the fourth data, respectively, may be input to the first through twelfth pixels PX1 through PX12 according to the assigned view areas.

For example, in an embodiment, light emitting elements included in the fourth pixel PX4, the eighth pixel PX8 and the twelfth pixel PX12 may emit light that forms the first viewing angle, and a data voltage input to these pixels may be formed from the first data. In an embodiment, the data voltage input to these pixels may include the first data.

For example, in an embodiment, light emitting elements included in the third pixel PX3, the seventh pixel PX7 and the eleventh pixel PX11 may emit light that forms the second viewing angle, and a data voltage input to these pixels may be formed from the second data. In an embodiment, the data voltage input to these pixels may include the second data.

For example, in an embodiment light emitting elements included in the second pixel PX2, the sixth pixel PX6 and the tenth pixel PX10 may emit light that forms the third viewing angle, and a data voltage input to these pixels may be formed from the third data. In an embodiment, the data voltage input to these pixels may include the third data.

For example, in an embodiment, light emitting elements included in the first pixel PX1, the fifth pixel PX5 and the ninth pixel PX9 may emit light that forms the fourth viewing angle, and a data voltage input to these pixels may be formed from the fourth data. In an embodiment, the data voltage input to these pixels may include the fourth data.

Therefore, the user’s left eye LE which perceives light traveling to the first view area V1 and the second view area V2 may perceive different image data from the user’s right eye RE which perceives light traveling to the third view area V3 and the fourth view area V4.

Since the left eye LE and the right eye RE of the user perceive different image data, the user may feel that a 3D image is realized from the first refractive area 3DIA_REF.

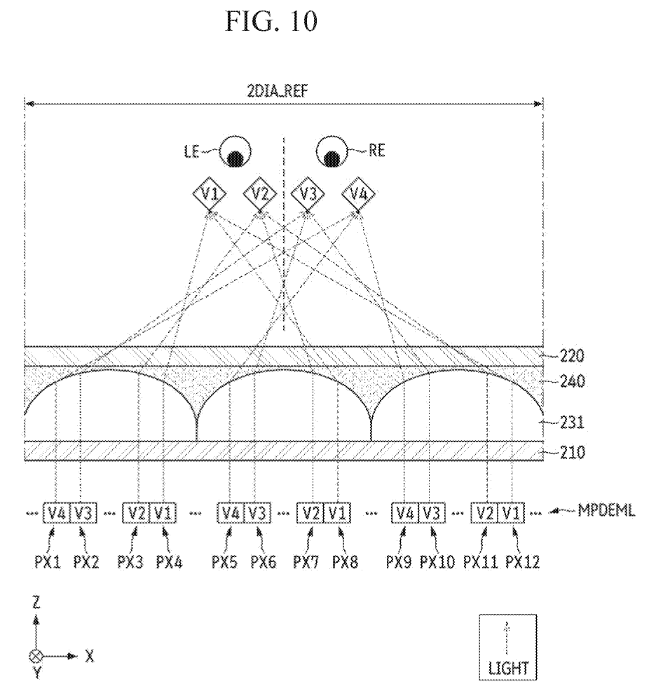

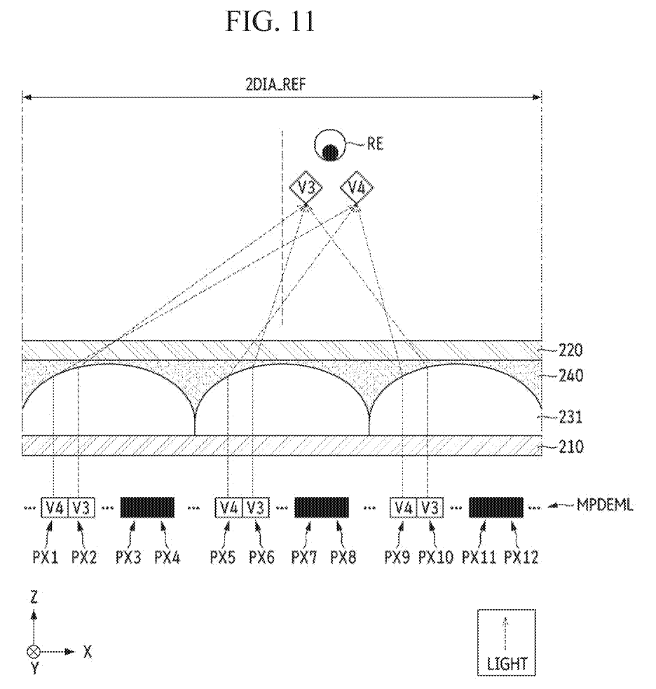

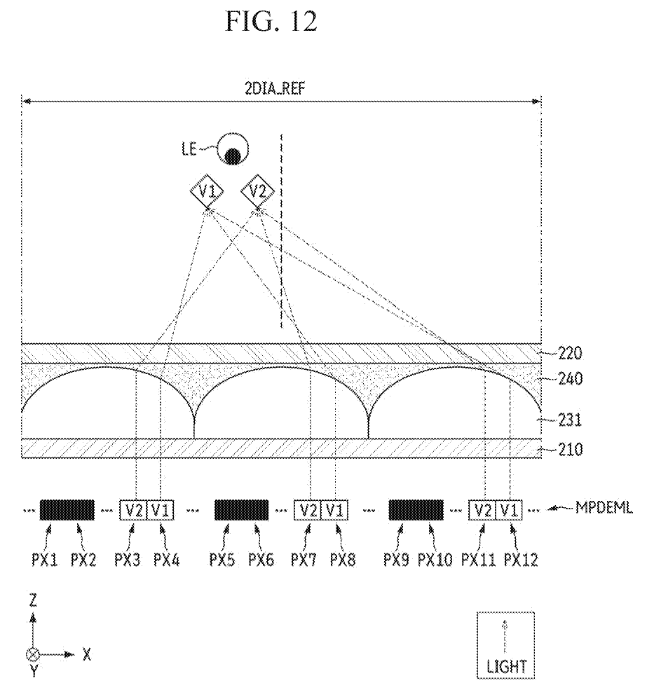

FIG. 10 is a cross-sectional view illustrating a case in which a 2D image is realized in an area where light is refracted. FIG. 11 is a cross-sectional view illustrating light incident on a user’s right eye RE in the area where light is refracted to realize a 2D image. FIG. 12 is a cross-sectional view illustrating light incident on the user’s left eye LE in the area where light is refracted to realize a 2D image. Elements having substantially the same functions as those of the above-described embodiment are indicated by like reference characters, and a repeated description thereof will be omitted.

Referring to FIG. 10, a display device according to an embodiment may include a refractive area including a second refractive area 2DIA_REF.

Both eyes LE and RE of a user may perceive refracted light. The user who perceives light emitted from the second refractive area 2DIA_REF may feel that a 2D image is realized from the second refractive area 2DIA_REF. In this case, image data perceived by the user’s left eye LE and image data perceived by the right eye RE may be the same. The user may feel that a 2D image is realized from the display device.

Light emitted from the second refractive area 2DIA_REF may be refracted. Light emitted from the display device according to an embodiment may travel to a first view area V1, a second view area V2, a third view area V3, and a fourth view area V4. However, the number of view areas is not limited to this example.

In an embodiment, an image data voltage formed from first data may be input to first through twelfth pixels PX1 through PX12 regardless of assigned view areas. In an embodiment, an image data voltage formed from second data may be input to the first through twelfth pixels PX1 through PX12 regardless of the assigned view areas. In an embodiment, an image data voltage formed from third data may be input to the first through twelfth pixels PX1 through PX12 regardless of the assigned view areas. In an embodiment, an image data voltage formed from fourth data may be input to the first through twelfth pixels PX1 through PX12 regardless of the assigned view areas.

For example, in an embodiment, light emitting elements included in the first through twelfth pixels PX1 through PX12 may emit light that forms first through fourth viewing angles according to the assigned view areas. However, a data voltage input to these pixels regardless of the various viewing angles may be formed from the first data. In an embodiment, the data voltage input to these pixels may include the first data.

For example, in an embodiment the light emitting elements included in the first through twelfth pixels PX1 through PX12 may emit light that forms the first through fourth viewing angles according to the assigned view areas. However, the data voltage input to these pixels regardless of the various viewing angles may be formed from the second data. In an embodiment, the data voltage input to these pixels may include the second data.

For example, in an embodiment, the light emitting elements included in the first through twelfth pixels PX1 through PX12 may emit light that forms the first through fourth viewing angles according to the assigned view areas. However, the data voltage input to these pixels regardless of the various viewing angles may be formed from the third data. In an embodiment, the data voltage input to these pixels may include the third data.

For example, in an embodiment, the light emitting elements included in the first through twelfth pixels PX1 through PX12 may emit light that forms the first through fourth viewing angles according to the assigned view areas. However, the data voltage input to these pixels regardless of the various viewing angles may be formed from the fourth data. In an embodiment, the data voltage input to these pixels may include the fourth data.

Therefore, the user’s left eye LE which perceives light traveling to the first view area V1 and the second view area V2 may perceive the same image data as the user’s right eye RE which perceives light traveling to the third view area V3 and the fourth view area V4.

Since the left eye LE and the right eye RE of the user perceive the same image data, the user may feel that a 2D image is realized from the second refractive area 2DIA_REF.

Referring to FIGS. 11 and 12, although all of the first through twelfth pixels PX1 through PX12 arranged in the display device emit light, each of the right eye RE and the left eye LE of the user may perceive only at least a portion of the light emitted from the pixels.

Light emitted from the second refractive area 2DIA_REF may be refracted. Light emitted from the display device according to an embodiment may travel to the first view area V1, the second view area V2, the third view area V3, and the fourth view area V4. However, the number of view areas is not limited to this example.

The third view area V3 and the fourth view area V4 may be disposed on the right eye side RE of the user, and the first view area V1 and the second view area V2 may be disposed on the left eye side LE of the user. Light emitted from pixels (PX1, PX2, PX5, PX6, PX9, PX10) to which the third view area V3 and the fourth view area V4 are assigned may be refracted by lenses 231 toward where the user’s right eye RE is disposed. Light emitted from pixels (PX3, PX4, PX7, PX8, PX11, PX12) to which the first view area V1 and the second view area V2 are assigned may be refracted by the lenses 231 toward where the user’s left eye LE is disposed.

Therefore, referring to FIG. 11, the user’s right eye RE may not perceive light emitted from the pixels (PX3, PX4, PX7, PX8, PX11, PX12) to which the first view area V1 and the second view area V2 are assigned.

In addition, referring to FIG. 12, the user’s left eye LE may not perceive light emitted from the pixels (PX1, PX2, PX5, PX6, PX9, PX10) to which the third view area V3 and the fourth view area V4 are assigned.

As described above, although all pixels arranged in a display panel emit light, each of the left eye LE and the right eye RE of the user may not perceive light emitted from pixels to which specific view areas are assigned. Accordingly, each of the right eye RE and the left eye LE of the user may not perceive at least a portion of the light emitted from the twelve pixels. In this case, the resolution perceived by the user looking at the second refractive area 2DIA_REF may be relatively low.

When a 3D image is realized, different image data is input to the left eye LE and the right eye RE of the user, so that the user can interpret an image as being a 3D image. However, as described above, when a 2D image is realized even though light is still refracted, the resolution of the display device perceived by the user may be reduced.

Embodiments of the present disclosure provide a display device which can prevent or mitigate such resolution reduction that may occur when a 2D image is realized in a refractive area.

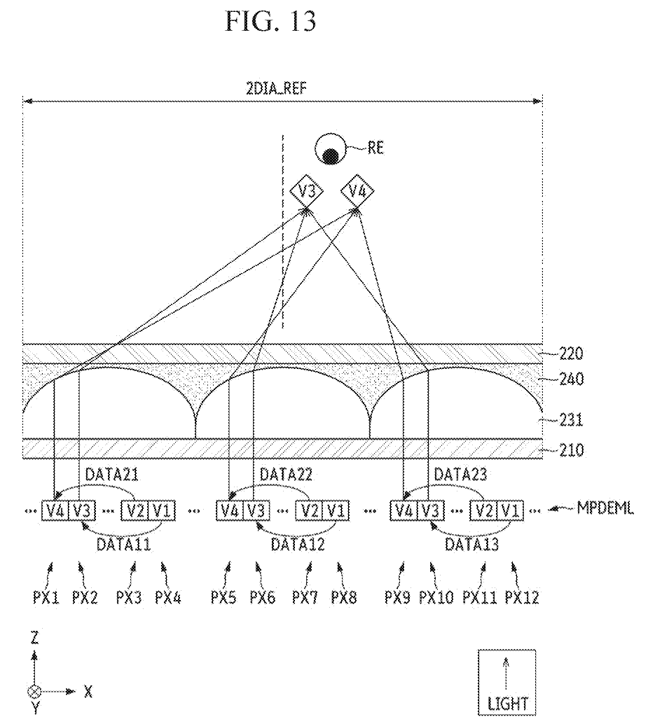

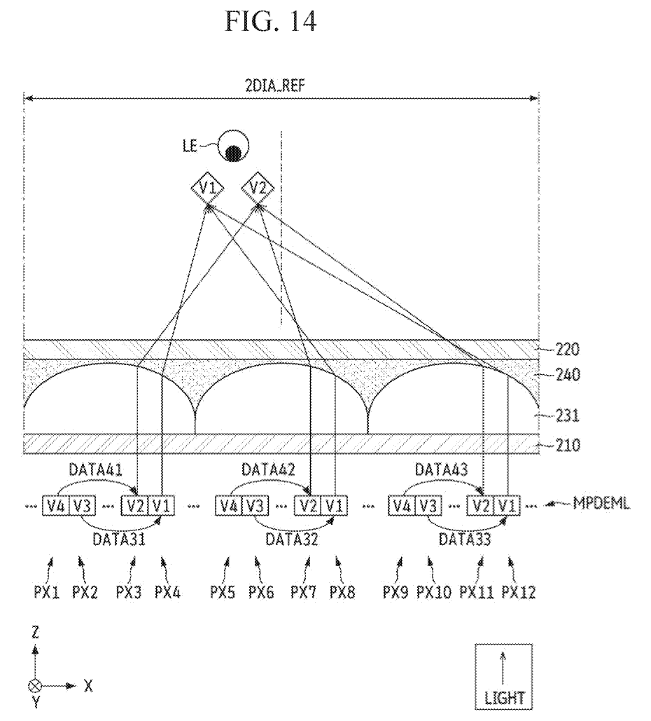

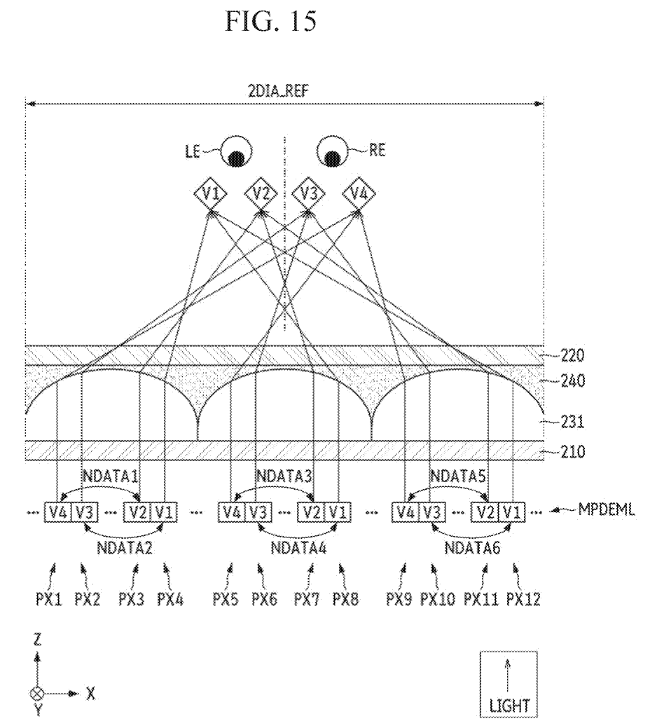

FIG. 13 is a cross-sectional view illustrating light incident on a user’s right eye RE in a display device according to an embodiment of the present disclosure. FIG. 14 is a cross-sectional view illustrating light incident on the user’s left eye LE in the display device according to an embodiment of the present disclosure. FIG. 15 is a cross-sectional view illustrating light incident on both eyes LE and RE of the user in the display device according to an embodiment of the present disclosure.

Referring to FIGS. 13 and 15, in the display device according to an embodiment, a first pixel PX1 to which a fourth view area V4 is assigned may receive a compensation data voltage including a data voltage DATA21 from a third pixel PX3 to which a second view area V2 is assigned. The compensation data voltage NDATA1 may be derived based on a data voltage that should be supplied to the first pixel PX1 and the data voltage DATA21 that should be supplied to the third pixel PX3.

A fifth pixel PX5 to which the fourth view area V4 is assigned may receive a compensation data voltage including a data voltage DATA22 from a seventh pixel PX7 to which the second view area V2 is assigned. The compensation data voltage NDATA3 may be derived based on a data voltage that should be supplied to the fifth pixel PX5 and the data voltage DATA22 that should be supplied to the seventh pixel PX7.

A ninth pixel PX9 to which the fourth view area V4 is assigned may receive a compensation data voltage including a data voltage DATA23 from an eleventh pixel PX11 to which the second view area V2 is assigned. The compensation data voltage NDATA5 may be derived based on a data voltage that should be supplied to the ninth pixel PX9 and the data voltage DATA23 that should be supplied to the eleventh pixel PX11.

In addition, a second pixel PX2 to which a third view area V3 is assigned may receive a compensation data voltage including a data voltage DATA11 from a fourth pixel PX4 to which a first view area V1 is assigned. The compensation data voltage NDATA2 may be derived based on a data voltage that should be supplied to the second pixel PX2 and the data voltage DATA11 that should be supplied to the fourth pixel PX4.

A sixth pixel PX6 to which the third view area V3 is assigned may receive a compensation data voltage including a data voltage DATA12 from an eighth pixel PX8 to which the first view area V1 is assigned. The compensation data voltage NDATA4 may be derived based on a data voltage that should be supplied to the sixth pixel PX6 and the data voltage DATA12 that should be supplied to the eighth pixel PX8.

A tenth pixel PX10 to which the third view area V3 is assigned may receive a compensation data voltage including a data voltage DATA13 from a twelfth pixel PX12 to which the first view area V1 is assigned. The compensation data voltage NDATA6 may be derived based on a data voltage that should be supplied to the tenth pixel PX10 and the data voltage DATA13 that should be supplied to the twelfth pixel PX12.

In the display device according to an embodiment, the application of compensation data voltages to pixels in the second refractive area 2DIA_REF may allow light perceived by the right eye RE to contain angularly differentiated content, even when displaying a 2D image. Rather than redundantly emitting the same data voltage across multiple pixels that map to different viewing angles V3 and V4, each compensation data voltage NDATA1, NDATA3, and NDATA5 may be tailored to partially reflect variations between those angles. This may enable the light refracted toward the right eye RE to more closely approximate the directional characteristics of a true 3D image, even though the content is fundamentally 2D, thereby suppressing the resolution degradation that would otherwise occur in the 2DIA_REF region.

Compensation data voltages may be derived based on data voltages that should be originally supplied to pixels other than pixels to which the third view area V3 and the fourth view area V4 corresponding to the right eye RE are assigned and data voltages that should be originally supplied to the pixels to which the third view area V3 and the fourth view area V4 are assigned. In an embodiment, a blur technique may be utilized as a method of deriving a compensation data voltage. The blur technique may be, but is not limited to, any one of Gaussian blur, box blur, median blur, motion blur, and bilateral blur. For example, in order to prevent a reduction in the resolution of an image perceived by the right eye RE, a data voltage, which corresponds to an average value of the data voltage that should be originally supplied to the third pixel PX3 and the data voltage that should be originally supplied to the first pixel PX1, may be input as a compensation data voltage to the first pixel PX1. However, the method of deriving a compensation data voltage is not limited to this example. A compensation data voltage may also be derived based on a data voltage that should be originally supplied to a pixel to which a view area other than a view area assigned to a pixel to which the compensation data voltage is to be supplied is assigned and a data voltage that should be originally supplied to the pixel to which the compensation data voltage is to be supplied. For example, the compensation data voltage may be derived as a weighted average of the data voltages that should be originally supplied.

According to embodiments, the use of blur-based processing techniques to derive the compensation data voltages reflects an approach in which spatial continuity between adjacent view areas is preserved, without replicating identical pixel data. In this way, the compensation data voltages input to light-emitting elements located in the second refractive area 2DIA_REF may simulate natural image gradients and transitions across the viewing angles. This may be effective in reducing edge aliasing and artificial sharpness loss in the perceived image. As a result, even though light continues to be refracted through the optical lens unit 230, the viewer may experience a smoother and higher-quality 2D image with enhanced fidelity in areas of rapid brightness or contrast transitions.

In addition, a positional criterion for determining the pixel to which the view area other than the view area assigned to the pixel to which the compensation data voltage is to be supplied is assigned may be adjusted. In the illustrated cross-sectional views, a compensation data voltage is derived based on a data voltage that should be originally supplied to a pixel (e.g., the third pixel PX3) disposed to the right of a pixel (e.g., the first pixel PX1) to which the compensation data voltage should be supplied. However, embodiments of the present disclosure are not limited to this case. For example, not only the data voltage that should be originally supplied to the pixel (e.g., the third pixel PX3) disposed to the right of the pixel (e.g., the first pixel PX1) to which the compensation data voltage should be supplied, but also a data voltage that should be originally supplied to a pixel (e.g., the seventh pixel PX7) disposed relatively further to the right may be utilized as a basis for deriving the compensation data voltage. This will be described in further detail below.

The ability to select source pixels for compensation data voltage derivation based on variable positional criteria may also introduce additional degrees of freedom in display calibration according to embodiments. For example, in scenarios where the pixel arrangement exhibits non-uniformities or where the viewer is off-axis, the system may adaptively select pixels from adjacent rows or diagonally spaced positions to derive improved or optimal compensation voltages. This flexibility supports improved spatial uniformity and perceptual coherence in 2D image display across the full extent of the second refractive area 2DIA_REF, thereby enhancing compatibility with different optical configurations or use cases such as curved or tilted display panels.

Referring to FIGS. 14 and 15, in the display device according to an embodiment, the third pixel PX3 to which the second view area V2 is assigned may receive a compensation data voltage including a data voltage DATA41 from the first pixel PX1 to which the fourth view area V4 is assigned. The compensation data voltage NDATA1 may be derived based on a data voltage that should be supplied to the third pixel PX3 and the data voltage DATA41 that should be supplied to the first pixel PX1.

The seventh pixel PX7 to which the second view area V2 is assigned may receive a compensation data voltage including a data voltage DATA42 from the fifth pixel PX5 to which the fourth view area V4 is assigned. The compensation data voltage NDATA3 may be derived based on a data voltage that should be supplied to the seventh pixel PX7 and the data voltage DATA42 that should be supplied to the fifth pixel PX5.

The eleventh pixel PX11 to which the second view area V2 is assigned may receive a compensation data voltage including a data voltage DATA43 from the ninth pixel PX9 to which the fourth view area V4 is assigned. The compensation data voltage NDATA5 may be derived based on a data voltage that should be supplied to the eleventh pixel PX11 and the data voltage DATA43 that should be supplied to the ninth pixel PX9.

In addition, the fourth pixel PX4 to which the first view area V1 is assigned may receive a compensation data voltage including a data voltage DATA31 from the second pixel PX2 to which the third view area V3 is assigned. The compensation data voltage NDATA2 may be derived based on a data voltage that should be supplied to the fourth pixel PX4 and the data voltage DATA31 that should be supplied to the second pixel PX2.

The eighth pixel PX8 to which the first view area V1 is assigned may receive a compensation data voltage including a data voltage DATA32 from the sixth pixel PX6 to which the third view area V3 is assigned. The compensation data voltage NDATA4 may be derived based on a data voltage that should be supplied to the eighth pixel PX8 and the data voltage DATA32 that should be supplied to the sixth pixel PX6.

The twelfth pixel PX12 to which the first view area V1 is assigned may receive a compensation data voltage including a data voltage DATA33 from the tenth pixel PX10 to which the third view area V3 is assigned. The compensation data voltage NDATA6 may be derived based on a data voltage that should be supplied to the twelfth pixel PX12 and the data voltage DATA33 that should be supplied to the tenth pixel PX10.

As in the case of the right eye RE, compensation data voltages NDATA2, NDATA4, and NDATA6 supplied to pixels mapping to the first view area V1 and second view area V2 can also be tailored to account for left-eye-specific characteristics according to embodiments. By incorporating angularly differentiated image information, even when displaying a 2D image, the device may avoid introducing view angle–based inconsistencies that can degrade image quality when viewed from the left eye LE. The resulting image may appear visually continuous and more natural, including in applications involving fast eye movements or viewer repositioning.

Compensation data voltages may be derived based on data voltages that should be originally supplied to pixels other than pixels to which the first view area V1 and the second view area V2 corresponding to the left eye LE are assigned and data voltages that should be originally supplied to the pixels to which the first view area V1 and the second view area V2 are assigned. In an embodiment, a blur technique may be utilized as a method of deriving a compensation data voltage. The blur technique may be, but is not limited to, any one of Gaussian blur, box blur, median blur, motion blur, and bilateral blur. For example, in order to prevent a reduction in the resolution of an image perceived by the left eye LE, a data voltage, which corresponds to an average value of the data voltage that should be originally supplied to the first pixel PX1 and the data voltage that should be originally supplied to the third pixel PX3, may be input as a compensation data voltage to the third pixel PX3. However, the method of deriving a compensation data voltage is not limited to this example. A compensation data voltage may also be derived based on a data voltage that should be originally supplied to a pixel to which a view area other than a view area assigned to a pixel to which the compensation data voltage is to be supplied is assigned and a data voltage that should be originally supplied to the pixel to which the compensation data voltage is to be supplied. For example, the compensation data voltage may be derived as a weighted average of the data voltages that should be originally supplied.

In addition to mitigating resolution loss, the use of compensation data voltages derived from processed source data may also improve the temporal stability of the perceived 2D image according to embodiments. For example, when frame-to-frame changes in viewpoint or motion content occur, the refracted emission from light-emitting elements in the second refractive area 2DIA_REF may still present consistent transitions across view areas. The blurring or weighted averaging process may effectively dampen harsh brightness shifts that could otherwise occur if the same unprocessed data voltages were indiscriminately duplicated across pixels. This may contribute to flicker reduction and improved visual comfort, including in larger display formats or wearable display environments.

In addition, a positional criterion for determining the pixel to which the view area other than the view area assigned to the pixel to which the compensation data voltage is to be supplied is assigned may be adjusted. In the illustrated cross-sectional views, a compensation data voltage is derived based on a data voltage that should be originally supplied to a pixel (e.g., the first pixel PX1) disposed to the left of a pixel (e.g., the third pixel PX3) to which the compensation data voltage should be supplied. However, embodiments of the present disclosure are not limited to this case. For example, not only the data voltage that should be originally supplied to the pixel (e.g., the first pixel PX1) disposed to the left of the pixel (e.g., the third pixel PX3) to which the compensation data voltage should be supplied, but also a data voltage that should be originally supplied to a pixel (e.g., the fifth pixel PX5) disposed to the right may be utilized as a basis for deriving the compensation data voltage. This will be described in detail below.

Furthermore, permitting compensation data voltage derivation from source pixels located on either side of the target pixel may allow the system according to an embodiment to adapt dynamically to asymmetries in the optical lens unit 230 or to non-uniform user eye positions. For example, in head-mounted display applications or when the user is positioned at an off-center angle relative to the display panel 110, the optimal mapping between light emission and view area may shift. By accommodating a broader set of spatial relationships, the voltage derivation process can be tuned to maintain consistent 2D image clarity across a wide range of viewing geometries.

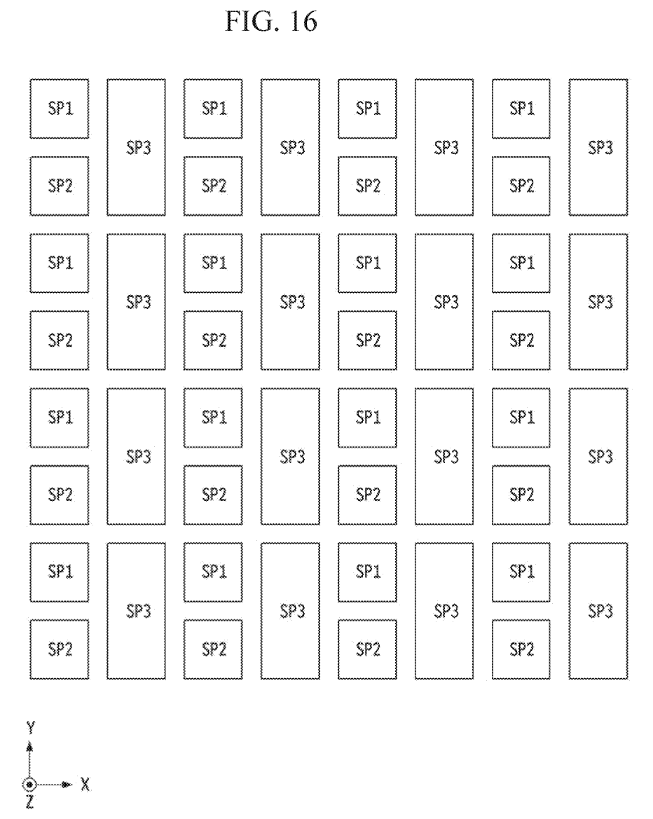

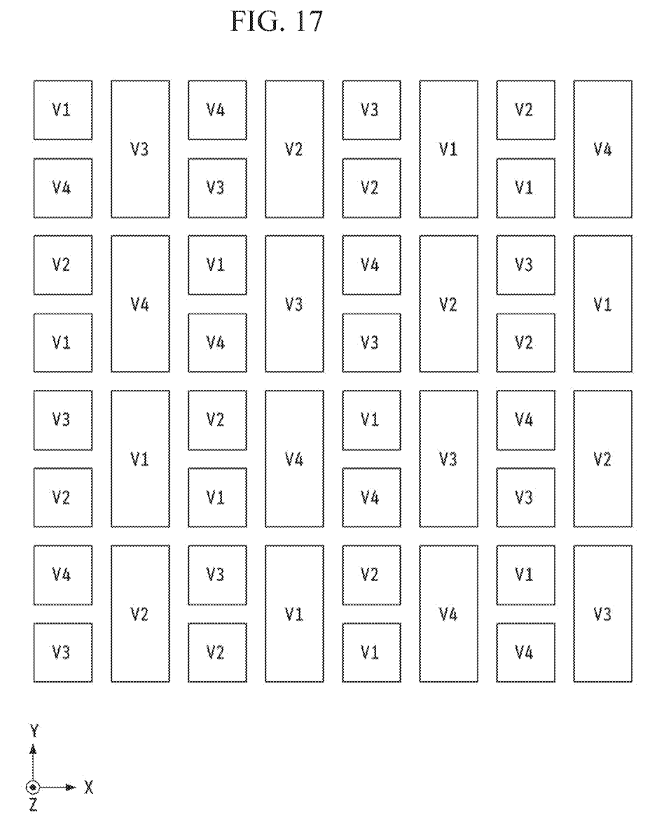

FIG. 16 is a plan view illustrating the arrangement of subpixels in a display device according to an embodiment of the present disclosure. FIG. 17 is a plan view illustrating viewing angles or view areas mapped to the subpixels arranged in the display device according to an embodiment of the present disclosure.

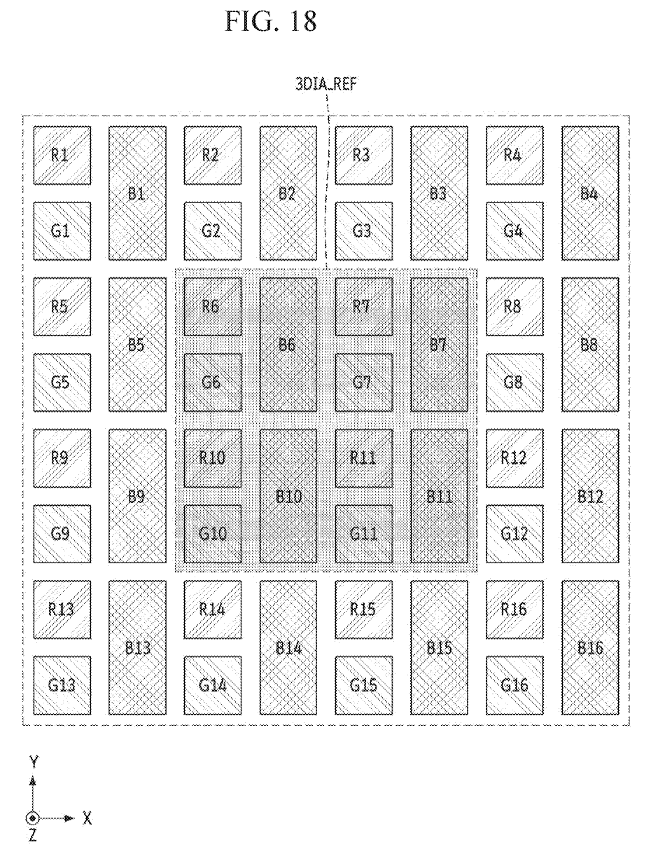

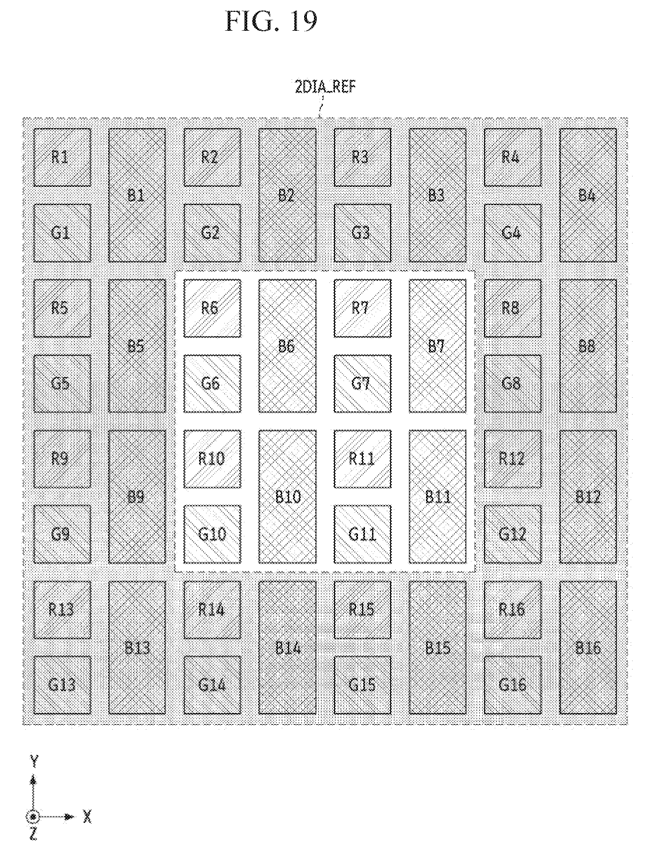

FIG. 18 is a plan view illustrating a first refractive area 3DIA_REF according to an embodiment of the present disclosure. FIG. 19 is a plan view illustrating a second refractive area 2DIA_REF according to an embodiment of the present disclosure.

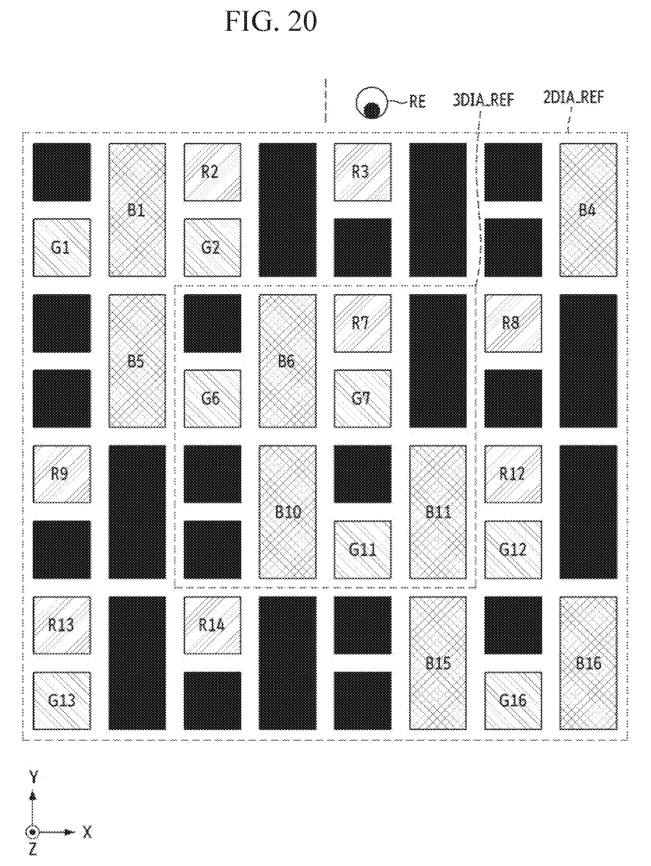

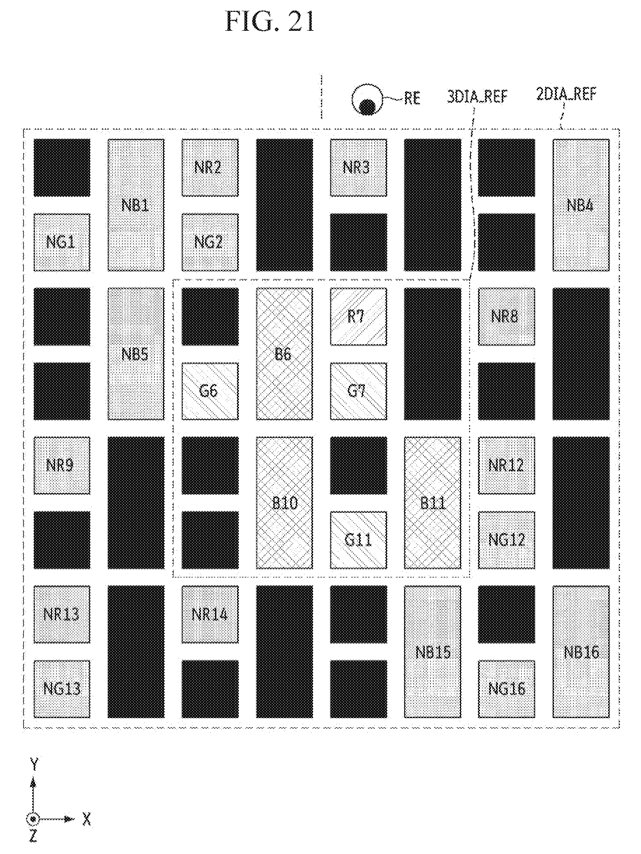

FIG. 20 is a plan view illustrating subpixels which emit light to be incident on a user’s right eye RE in refractive areas according to an embodiment of the present disclosure. FIG. 21 is a plan view schematically illustrating data voltages and compensation data voltages applied to the subpixels which emit light to be incident on the user’s right eye RE in the refractive areas according to an embodiment of the present disclosure. Reference characters starting with R, G, and B indicate data voltages supplied to corresponding subpixels, and reference characters starting with NR, NG, and NB indicate compensation data voltages supplied to corresponding subpixels. Numbers indicate the order of corresponding subpixels.

Referring to FIG. 20, in an embodiment, a first view area V1 and a second view area V2 may be disposed on the left eye side LE of the user, and a third view area V3 and a fourth view area V4 may be disposed on the right eye side RE of the user. Although all subpixels arranged in a display device emit light, the user’s right eye RE cannot perceive light emitted from subpixels to which the first view area V1 and the second view area V2 are assigned. Therefore, the resolution perceived by the user’s right eye RE may be relatively reduced.

This is a phenomenon that occurs regardless of the first refractive area 3DIA_REF and the second refractive area 2DIA_REF. In the first refractive area 3DIA_REF where a 3D image is realized, since different images must be perceived by the left eye LE and the right eye RE, the degree of the resolution reduction described above may be relatively low. However, in the second refractive area 2DIA_REF where a 2D image is realized, the same image must be perceived by the left eye LE and the right eye RE, and the degree of the resolution reduction may be relatively high.

For example, when a 2D image is displayed in the second refractive area 2DIA_REF, all subpixels may emit light based on the same image data for both eyes, but a portion of that emitted light may remain outside the perceivable angular range of each eye. This may lead to a loss in effective resolution, since some image data fails to contribute to the perceived image. Unlike in 3D mode, where separate data for the left eye LE and the right eye RE are naturally distributed across available view areas, the uniformity of the 2D image content may exacerbate the perception of reduced sharpness. Accordingly, embodiments may address this drawback by tailoring compensation data voltages in a manner that preserves angular distribution and supports visual continuity, even for 2D content.

Referring to FIG. 21, in a display device according to an embodiment, compensation data voltages may be input to subpixels to which view areas disposed on the right eye side RE of the user are assigned among a plurality of subpixels disposed in the second refractive area 2DIA_REF. Data voltages that should be originally supplied may be input to a plurality of subpixels disposed in the first refractive area 3DIA_REF.

The supply of compensation data voltages to subpixels assigned to the right eye RE in the second refractive area 2DIA_REF may serve to populate light output across multiple viewing angles with differentiated voltage profiles, thereby reconstructing spatial detail that would otherwise be lost. This may enable the user’s right eye RE to receive image content from view areas V3 and V4 that is not merely duplicated, but derived to simulate angular variance, thereby increasing the effective resolution and perceived clarity of the 2D image. The may improve image fidelity without requiring additional physical subpixels or changes to the lens array structure.

In an embodiment, first data through fourth data may be derived by collecting specific content at first through fourth viewing angles. In addition, fifth data and sixth data may be derived based on the first data and the second data collected at the first viewing angle and the second viewing angle. For example, the fifth data may be derived from the first data by utilizing a blur technique, and the sixth data may be derived from the second data by utilizing the blur technique. In the present specification, data voltage and data may be substantially the same concept.

A compensation data voltage formed from the fifth data may be formed from the fifth data derived based on the first data and the third data or may be derived based on image data voltages formed from the first data and the third data. The blur technique may be utilized to derive the fifth data based on the first data and the third data. The blur technique may also be applied and utilized to derive the compensation data voltage based on the image data voltages formed from the first data and the third data.

A compensation data voltage formed from the sixth data may be formed from the sixth data derived based on the second data and the fourth data or may be derived based on image data voltages formed from the second data and the fourth data. The blur technique may be utilized to derive the sixth data based on the second data and the fourth data. The blur technique may also be applied and utilized to derive the compensation data voltage based on the image data voltages formed from the second data and the fourth data.

The use of blur techniques to derive compensation data voltages may enable smooth transitions between neighboring view areas by interpolating between distinct sets of image data. In the context of a 2D image, where the same visual content is intended for both eyes, this interpolation may help preserve continuity in high-frequency details such as edges and textures, while reducing abrupt luminance or chromatic variations that might otherwise arise when multiple view angles are populated using uniform voltage values. The result is a more natural visual presentation across the second refractive area 2DIA_REF, including when viewed from intermediate positions between defined view angles.

A data voltage input to the first refractive area 3DIA_REF among the third data and the fourth data may be supplied to the first refractive area 3DIA_REF where a 3D image is realized. The third data is data about the third viewing angle, and the fourth data is data about the fourth viewing angle. Therefore, an image input to the right eye RE may include information about the third data and the fourth data. Since this information is different from the first data and the second data as an image input to the left eye LE which will be described further below, a 3D image may be realized from the first refractive area 3DIA_REF.

A compensation data voltage input to the second refractive area 2DIA_REF among the fifth data and the sixth data may be supplied to the second refractive area 2DIA_REF where a 2D image is realized. The fifth data is derived based on the first data and the third data, and the sixth data is derived based on the second data and the fourth data. Therefore, an image input to the right eye RE may include information about all of the first data through the fourth data. Since this information is the same as the fifth data and the sixth data as an image input to the left eye LE which will be described further below, a 2D image with a compensated resolution may be realized from the second refractive area 2DIA_REF.

By incorporating information from multiple view angles into the compensation data voltages supplied to the second refractive area 2DIA_REF, the display device according to embodiments may generate light emission that maintains angular coherence across both eyes. This may suppress artifacts that might result from refracted light diverging from ideal alignment. Embodiments may allow 2D images to be displayed in the refracted region without the noticeable softening or ghosting typically associated with light field displays configured for stereoscopic use.

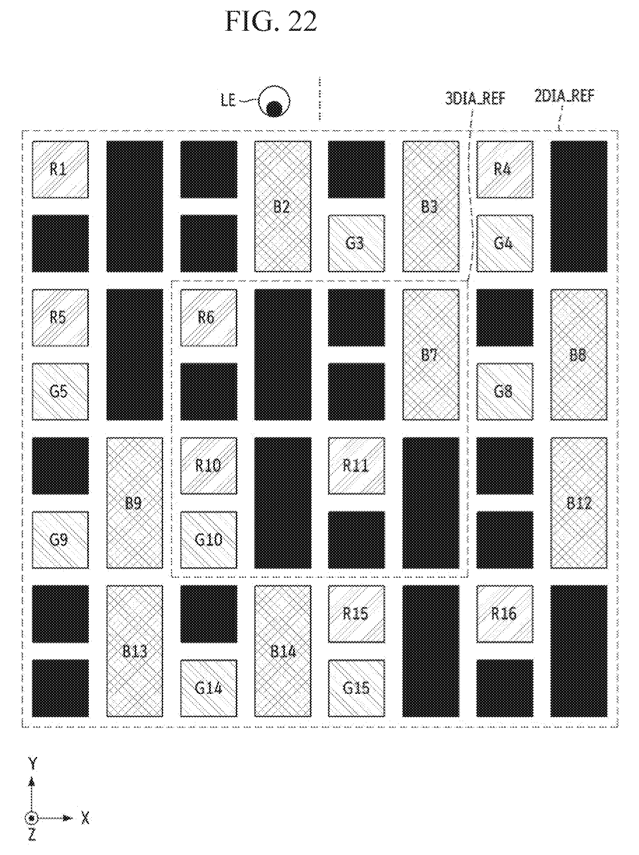

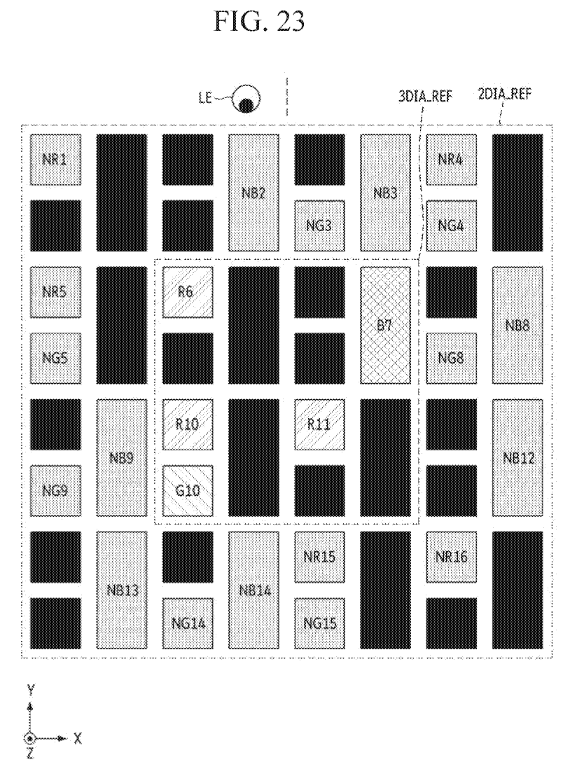

FIG. 22 is a plan view illustrating subpixels which emit light to be incident on a user’s left eye LE in refractive areas according to an embodiment of the present disclosure. FIG. 23 is a plan view schematically illustrating data voltages and compensation data voltages applied to the subpixels which emit light to be incident on the user’s left eye LE in the refractive areas according to an embodiment of the present disclosure. Reference characters starting with R, G, and B indicate data voltages supplied to corresponding subpixels, and reference characters starting with NR, NG, and NB indicate compensation data voltages supplied to corresponding subpixels. Numbers indicate the order of corresponding subpixels.

Referring to FIG. 22, in an embodiment, a first view area V1 and a second view area V2 may be disposed on the left eye side LE of the user, and a third view area V3 and a fourth view area V4 may be disposed on the right eye side RE of the user. Although all subpixels arranged in a display device emit light, the user’s left eye LE cannot perceive light emitted from subpixels to which the third view area V3 and the fourth view area V4 are assigned. Therefore, the resolution perceived by the user’s left eye LE may be relatively reduced.

This is a phenomenon that occurs regardless of a first refractive area 3DIA_REF and a second refractive area 2DIA_REF. In the first refractive area 3DIA_REF where a 3D image is realized, since different images must be perceived by the left eye LE and the right eye RE, the degree of the resolution reduction described above may be relatively low. However, in the second refractive area 2DIA_REF where a 2D image is realized, the same image must be perceived by the left eye LE and the right eye RE, and the degree of the resolution reduction may be relatively high.

Referring to FIG. 23, in a display device according to an embodiment, compensation data voltages may be input to subpixels to which view areas disposed on the left eye side LE of the user are assigned among a plurality of subpixels disposed in the second refractive area 2DIA_REF. Data voltages that should be originally supplied may be input to a plurality of subpixels disposed in the first refractive area 3DIA_REF.

Just as with the right eye RE, the application of compensation data voltages to subpixels assigned to the left eye LE in the second refractive area 2DIA_REF may introduce angular variation in emitted light that reconstructs spatial detail otherwise lost due to refractive mapping. This may maintain balance in resolution perception between the two eyes and support binocular visual comfort, especially in situations where head position or eye alignment deviates from the optical axis of the display panel. This approach may improve the consistency of the 2D viewing experience across different user positions and postures.

In an embodiment, first data through fourth data may be derived by collecting specific content at first through fourth viewing angles. In addition, fifth data and sixth data may be derived based on the third data and the fourth data collected at the third viewing angle and the fourth viewing angle. For example, the fifth data may be derived from the third data by utilizing a blur technique, and the sixth data may be derived from the fourth data by utilizing the blur technique. In the present specification, data voltage and data may be substantially the same concept.

A compensation data voltage formed from the fifth data may be formed from the fifth data derived based on the first data and the third data or may be derived based on image data voltages formed from the first data and the third data. The blur technique may be utilized to derive the fifth data based on the first data and the third data. The blur technique may also be applied and utilized to derive the compensation data voltage based on the image data voltages formed from the first data and the third data.

A compensation data voltage formed from the sixth data may be formed from the sixth data derived based on the second data and the fourth data or may be derived based on image data voltages formed from the second data and the fourth data. The blur technique may be utilized to derive the sixth data based on the second data and the fourth data. The blur technique may also be applied and utilized to derive the compensation data voltage based on the image data voltages formed from the second data and the fourth data.

A data voltage input to the first refractive area 3DIA_REF among the first data and the second data may be supplied to the first refractive area 3DIA_REF where a 3D image is realized. The first data is data about the first viewing angle, and the second data is data about the second viewing angle. Therefore, an image input to the left eye LE may include information about the first data and the second data. Since this information is different from the third data and the fourth data as an image input to the right eye RE described above, a 3D image may be realized from the first refractive area 3DIA_REF.

A compensation data voltage input to the second refractive area 2DIA_REF among the fifth data and the sixth data may be supplied to the second refractive area 2DIA_REF where a 2D image is realized. The fifth data is derived based on the first data and the third data, and the sixth data is derived based on the second data and the fourth data. Therefore, an image input to the left eye LE may include information about all of the first data through the fourth data. Since this information is the same as the fifth data and the sixth data as an image input to the right eye RE described above, a 2D image with a compensated resolution may be realized from the second refractive area 2DIA_REF.

The ability to synthesize fifth and sixth data based on content from all four view angles may permit a more robust and adaptable rendering strategy for the second refractive area 2DIA_REF. This may improve image legibility and spatial definition in content with fine structural details (e.g., text), where resolution degradation would otherwise compromise usability. Moreover, by balancing the angular distribution of image content across both the left eye LE and right eye RE, embodiments may may mitigate perceptual inconsistencies during head movement or off-axis viewing.

The display device according to an embodiment of the present disclosure includes the first refractive area 3DIA_REF and the second refractive area 2DIA_REF and can eliminate or reduce resolution reduction that occurs in the second refractive area 2DIA_REF.

Compared to stereoscopic displays according to comparative examples, which suffer from resolution loss in refractive 2D regions due to redundant image projection, the display device according to embodiments achieves enhanced effective resolution by actively shaping the compensation data voltages for each subpixel in the second refractive area 2DIA_REF. This approach may support accurate reproduction of 2D content in mixed-mode displays (e.g., devices capable of switching between 2D and 3D modes), while avoiding the trade-offs in sharpness and brightness typically associated with light-field rendering. The configuration may also facilitate backward compatibility with existing 2D video content without modification.

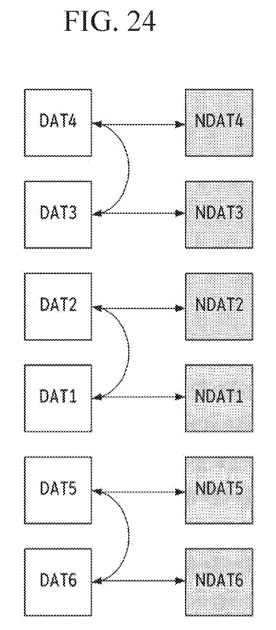

FIGS. 24 through 30 are plan views schematically illustrating positional criteria for determining compensation data voltages according to an embodiment of the present disclosure.

The positional criteria for deriving compensation data voltages may or may not be related to mapped view areas. The positional criteria may be within the design specifications of those of ordinary skill in the art and may be appropriately changed depending on the application.

In FIGS. 24 through 28, subpixels to which a fourth data voltage DAT4, a third data voltage DAT3, a second data voltage DAT2, a first data voltage DAT1, a fifth data voltage DAT5 and a sixth data voltage DAT6 are applied may be arranged side by side in the first direction.

Referring to FIG. 24, a fourth compensation data voltage NDAT4 may be derived based on the fourth data voltage DAT4 and the third data voltage DAT3 that should be originally supplied. A blur technique may be utilized as a derivation method. For example, the fourth compensation data voltage NDAT4 may be an average or a weight average of the third data voltage DAT3 and the fourth data voltage DAT4.

A third compensation data voltage NDAT3 may also be derived based on the fourth data voltage DAT4 and the third data voltage DAT3 that should be originally supplied. A blur technique may be utilized as a derivation method. For example, the third compensation data voltage NDAT3 may be an average or a weighted average of the third data voltage DAT3 and the fourth data voltage DAT4.

A second compensation data voltage NDAT2 may be derived based on the second data voltage DAT2 and the first data voltage DAT1 that should be originally supplied. A blur technique may be utilized as a derivation method. For example, the second compensation data voltage NDAT2 may be an average or a weighted average of the first data voltage DAT1 and the second data voltage DAT2.

A first compensation data voltage NDAT1 may also be derived based on the second data voltage DAT2 and the first data voltage DAT1 that should be originally supplied. A blur technique may be utilized as a derivation method. For example, the first compensation data voltage NDAT1 may be an average or a weighted average of the first data voltage DAT1 and the second data voltage DAT2.

A fifth compensation data voltage NDAT5 may be derived based on the fifth data voltage DAT5 and the sixth data voltage DAT6 that should be originally supplied. A blur technique may be utilized as a derivation method. For example, the fifth compensation data voltage NDAT5 may be an average or a weighted average of the sixth data voltage DAT6 and the fifth data voltage DAT5.

A sixth compensation data voltage NDAT6 may also be derived based on the fifth data voltage DAT5 and the sixth data voltage DAT6 that should be originally supplied. A blur technique may be utilized as a derivation method. For example, the sixth compensation data voltage NDAT6 may be an average or a weighted average of the sixth data voltage DAT6 and the fifth data voltage DAT5.

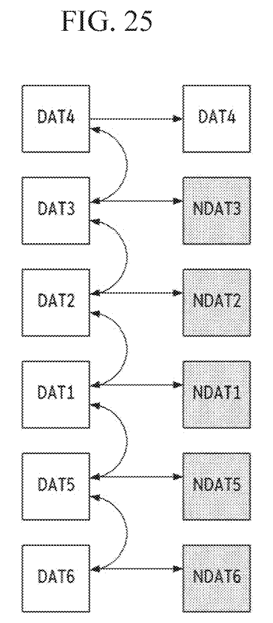

Referring to FIG. 25, the fourth data voltage DAT4 may be input as it is, and compensation data voltages may be input to other pixels.

For example, the third compensation data voltage NDAT3 may be derived based on the third data voltage DAT3 and the fourth data voltage DAT4, the second compensation data voltage NDAT2 may be derived based on the second data voltage DAT2 and the third data voltage DAT3, the first compensation data voltage NDAT1 may be derived based on the first data voltage DAT1 and the second data voltage DAT2, the fifth compensation data voltage NDAT5 may be derived based on the fifth data voltage DAT5 and the first data voltage DAT1, and the sixth compensation data voltage NDAT6 may be derived based on the sixth data voltage DAT6 and the fifth data voltage DAT5.

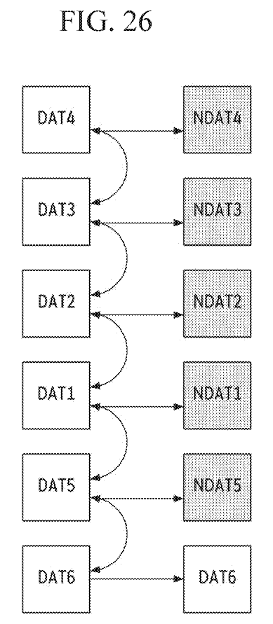

Referring to FIG. 26, the sixth data voltage DAT6 may be input as it is, and compensation data voltages may be input to other pixels.

For example, the fourth compensation data voltage NDAT4 may be derived based on the fourth data voltage DAT4 and the third data voltage DAT3, the third compensation data voltage NDAT3 may be derived based on the third data voltage DAT3 and the second data voltage DAT2, the second compensation data voltage NDAT2 may be derived based on the second data voltage DAT2 and the first data voltage DAT1, the first compensation data voltage NDAT1 may be derived based on the first data voltage DAT1 and the fifth data voltage DAT5, and the fifth compensation data voltage NDAT5 may be derived based on the fifth data voltage DAT5 and the sixth data voltage DAT6.

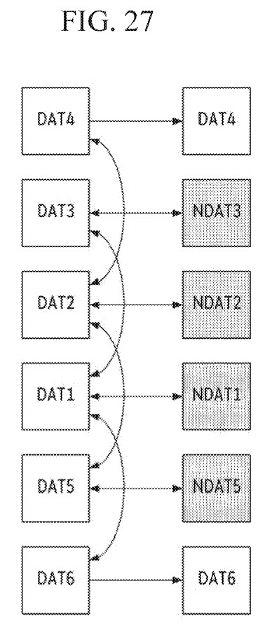

Referring to FIG. 27, the fourth data voltage DAT4 and the sixth data voltage DAT6 may be input as they are, and compensation data voltages may be input to other pixels.

For example, the third compensation data voltage NDAT3 may be derived based on the fourth data voltage DAT4, the third data voltage DAT3 and the second data voltage DAT2, the second compensation data voltage NDAT2 may be derived based on the third data voltage DAT3, the second data voltage DAT2 and the first data voltage DAT1, the first compensation data voltage NDAT1 may be derived based on the second data voltage DAT2, the first data voltage DAT1 and the fifth data voltage DAT5, and the fifth compensation data voltage NDAT5 may be derived based on the first data voltage DAT1, the fifth data voltage DAT5 and the sixth data voltage DAT6.

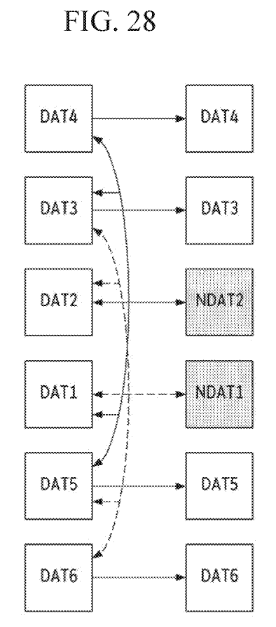

Referring to FIG. 28, the fourth data voltage DAT4, the third data voltage DAT3, the fifth data voltage DAT5 and the sixth data voltage DAT6 may be input as they are, and compensation data voltages may be input to other pixels.

For example, the second compensation data voltage NDAT2 may be derived based on the fourth data voltage DAT4, the third data voltage DAT3, the second data voltage DAT2, the first data voltage DAT1 and the fifth data voltage DAT5, and the first compensation data voltage NDAT1 may be derived based on the third data voltage DAT3, the second data voltage DAT2, the first data voltage DAT1, the fifth data voltage DAT5 and the sixth data voltage DAT6.

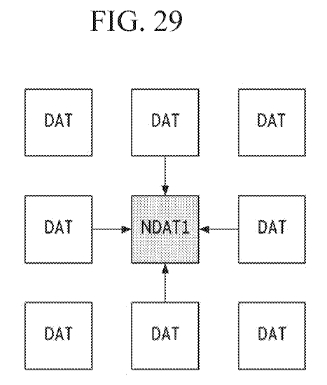

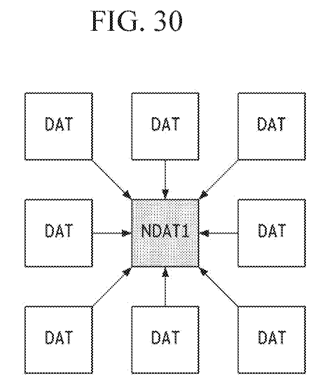

Referring to FIGS. 29 and 30, in an embodiment, the first compensation data voltage NDAT1, which is derived based on data voltages that should be originally supplied to subpixels disposed above, below, to the left and to the right of a corresponding subpixel to which the first data voltage DAT1 should be originally supplied, may be supplied to the corresponding subpixel. In an embodiment, the first compensation data voltage NDAT1 derived based on data voltages that should be originally supplied to all subpixels around the corresponding subpixel may be supplied to the corresponding subpixel.

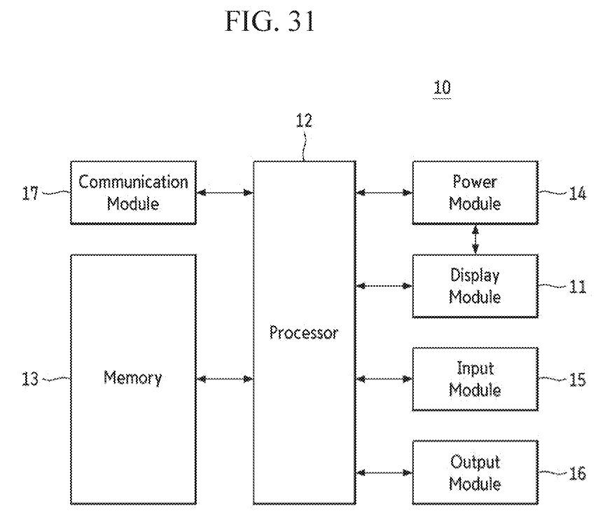

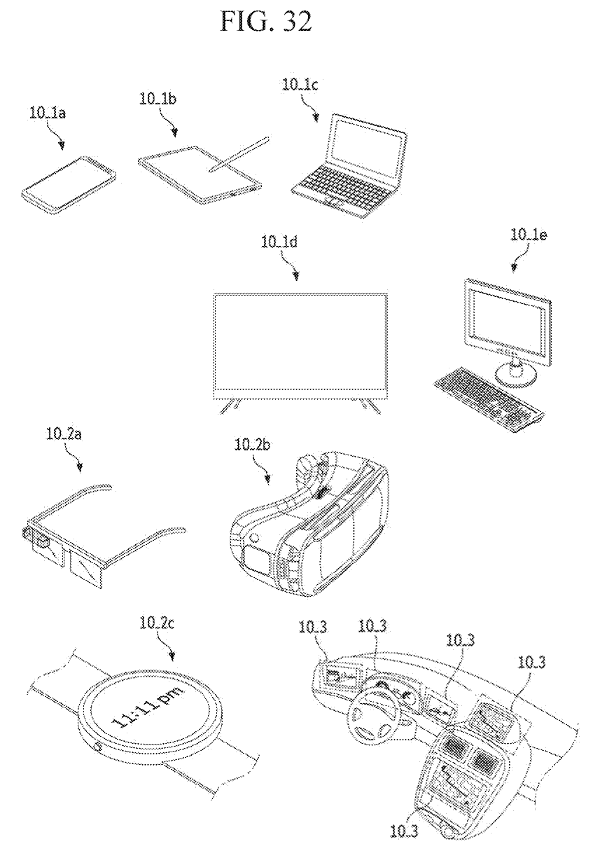

FIG. 31 is a block diagram of an electronic device according to an embodiment of the present disclosure. FIG. 32 is a schematic diagram of electronic devices according to various embodiments of the present disclosure.

Referring to FIG. 31, an electronic device 10 according to an embodiment may include a display module 11 (also referred to as a display device), a processor 12, a memory 13, and a power module 14 (also referred to as a power device). The display module 11 may be the same as the display module 100 according to FIG. 1 described above.

The processor 12 may include at least one of, for example, a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate power necessary for the operation of the electronic device 10 by converting power supplied by the power supply module.

At least one of the elements of the electronic device 10 described above may be included in a display device according to the above-described embodiments. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 10.

Referring to FIG. 32, various electronic devices to which a display device according to embodiments of the present disclosure is applied may include image display electronic devices such as a smartphone 10_1a, a tablet computer 10_1b, a laptop 10_1c, a television 10_1d, and a computer monitor 10_1e. In addition, the various electronic devices to which the display device according to an embodiments of the present disclosure is applied may include wearable electronic devices including display modules, such as smart glasses 10_2a, a head-mounted display 10_2b and a smart watch 10_2c, and vehicle electronic devices 10_3 including display modules, such as a center information display (CID) and a room mirror display disposed on an instrument cluster, a center fascia and a dashboard of a vehicle.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. In embodiments, each block, unit and/or module may be implemented by dedicated hardware, or as a combination of dedicated hardware to perform some functions and a processor (e.g., one or more programmed microprocessors and associated circuitry) to perform other functions.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a display driver configured to output an image data voltage;
a display panel comprising a first refractive area and a second refractive area in which a plurality of light emitting elements configured to receive the image data voltage from the display driver and emit light is disposed; and
an optical lens unit configured to refract the light emitted from the plurality of light emitting elements disposed in the first refractive area and the light emitted from the plurality of light emitting elements disposed in the second refractive area,
wherein the image data voltage comprises a plurality of data voltages supplied to the light emitting elements, respectively, and a plurality of compensation data voltages derived based on the data voltages, the light emitting elements disposed in the first refractive area receive the data voltages, and the light emitting elements disposed in the second refractive area receive the compensation data voltages.

2. The display device of claim 1, wherein the light emitted from the light emitting elements disposed in the first refractive area forms a first viewing angle and a second viewing angle, and the light emitted from the light emitting elements disposed in the second refractive area forms a third viewing angle and a fourth viewing angle.

3. The display device of claim 1, wherein the light emitted from the light emitting elements disposed in the first refractive area forms a first viewing angle and a second viewing angle, and in the first refractive area, a data voltage input to a light emitting element which emits light that forms the first viewing angle is different from a data voltage input to a light emitting element which emits light that forms the second viewing angle.

4. The display device of claim 3, wherein a plurality of data voltages input to a plurality of light emitting elements which emit light that forms the first viewing angle in the first refractive area are formed from first data generated by collecting specific content at the first viewing angle, and a plurality of data voltages input to a plurality of light emitting elements which emit light that forms the second viewing angle in the first refractive area are formed from second data generated by collecting the specific content at the second viewing angle.

5. The display device of claim 1, wherein the light emitted from the light emitting elements disposed in the second refractive area forms a first viewing angle and a second viewing angle, and in the second refractive area, a compensation data voltage input to a light emitting element which emits light that forms the first viewing angle is about equal to a compensation data voltage input to a light emitting element which emits light that forms the second viewing angle.

6. The display device of claim 5, wherein a plurality of compensation data voltages input to a plurality of light emitting elements which emit light that forms the first viewing angle in the second refractive area are formed from third data derived from first data generated by collecting specific data at the first viewing angle, and a plurality of compensation data voltages input to a plurality of light emitting elements which emit light that forms the second viewing angle in the second refractive area are formed from the third data.

7. The display device of claim 6, wherein the light emitted from the first refractive area forms the first viewing angle and the second viewing angle, and a data voltage input to a light emitting element which emits light that forms the first viewing angle is different from a data voltage input to a light emitting element which emits light that forms the second viewing angle.

8. The display device of claim 7, wherein a plurality of data voltages input to a plurality of light emitting elements which emit light that forms the first viewing angle in the first refractive area are different from a plurality of compensation data voltages input to a plurality of light emitting elements which emit light that forms the first viewing angle in the second refractive area.

9. The display device of claim 8, wherein the data voltages input to the light emitting elements which emit the light that forms the first viewing angle in the first refractive area are formed from the first data, and the compensation data voltages input to the light emitting elements which emit the light that forms the first viewing angle in the second refractive area are formed from the third data.

10. The display device of claim 1, wherein the data voltages are formed from first data generated by collecting specific content at a first viewing angle and second data generated by collecting the specific content at a second viewing angle, and the compensation data voltages are formed from third data derived based on the first data.

11. The display device of claim 10, wherein the light emitting elements disposed in the first refractive area receive a data voltage input to the first refractive area among the first data and a data voltage input to the first refractive area among the second data.

12. The display device of claim 10, wherein the light emitting elements disposed in the second refractive area receive a compensation data voltage input to the second refractive area among the third data.

13. The display device of claim 12, wherein the light emitting elements disposed in the first refractive area receive a data voltage input to the first refractive area among the first data and a data voltage input to the first refractive area among the second data.

14. The display device of claim 10, wherein the third data comprises data obtained by processing the first data using a blur technique.

15. The display device of claim 14, wherein the blur technique is any one of Gaussian blur, box blur, median blur, motion blur, and bilateral blur technique.

16. An electronic device, comprising:
a processor configured to provide an image signal;
a display device configured to receive the image signal from the processor and display an image; and
a power device configured to supply power to the display device,
wherein the display device comprises:
a display panel comprising a first refractive area and a second refractive area in which a plurality of light emitting elements configured to receive the image signal and emit light is disposed; and
an optical lens unit configured to refract the light emitted from the plurality of light emitting elements disposed in the first refractive area and the light emitted from the plurality of light emitting elements disposed in the second refractive area,
wherein the image signal comprises a plurality of data voltages supplied to the light emitting elements, respectively, and a plurality of compensation data voltages derived based on the data voltages, the light emitting elements disposed in the first refractive area receive the data voltages, and the light emitting elements disposed in the second refractive area receive the compensation data voltages.

17. The electronic device of claim 16, wherein the light emitted from the light emitting elements disposed in the first refractive area forms a first viewing angle and a second viewing angle, and in the first refractive area, a data voltage input to a light emitting element which emits light that forms the first viewing angle is different from a data voltage input to a light emitting element which emits light that forms the second viewing angle.

18. The electronic device of claim 17, wherein the light emitted from the light emitting elements disposed in the second refractive area forms a third viewing angle and a fourth viewing angle, and in the second refractive area, a compensation data voltage input to a light emitting element which emits light that forms the third viewing angle is as about equal to a compensation data voltage input to a light emitting element which emits light that forms the fourth viewing angle.

19. The electronic device of claim 16, wherein the data voltages are formed from first data generated by collecting specific content at a first viewing angle and second data generated by collecting the specific content at a second viewing angle, and the compensation data voltages are formed from third data derived based on the first data.

20. The electronic device of claim 19, wherein the light emitting elements disposed in the first refractive area receive a data voltage input to the first refractive area among the first data and a data voltage input to the first refractive area among the second data, and the light emitting elements disposed in the second refractive area receive a compensation data voltage input to the second refractive area among the third data.
